(19) United States
(12) Patent Application Publication
(10) Pub. No.: US 2009/0021888 A1
(43) Pub. Date: Jan. 22, 2009

(54) CAPACITOR, METHOD OF MANUFACTURING A CAPACITOR AND METHOD OF MANUFACTURING A SEMICONDUCTOR DEVICE

(76) Inventor: DONG JIN JUNG, Yongin-si (KR)

Correspondence Address: F. CHAU & ASSOCIATES, LLC, 130 WOODBURY ROAD, WOODBURY, NY, 11797, US

(21) Appl. No.: 12/174,390

(22) Filed: Jul. 16, 2008

(30) Foreign Application Priority Data
Jul. 16, 2007 (KR) 2007-70938

(51) Int. Cl. H01G 4/06; H01G 7/06; H01L 21/02

(52) U.S. Cl. 361/303; 29/25.42; 438/3; 257/E21.008

(57) ABSTRACT

A capacitor includes a lower electrode structure which includes a sidewall, an upper surface and a rounded surface between the sidewall and the upper surface. The capacitor further includes a ferroelectric layer pattern disposed on the lower electrode structure, and an upper electrode structure is provided on the ferroelectric layer pattern. The ferroelectric layer pattern is formed on the upper surface, the sidewall and the rounded surface of the lower electrode structure. The effective area between the lower electrode structure and the ferroelectric layer pattern may be increased, and the crystalline structure of the ferroelectric layer pattern may be improved. Accordingly, the capacitor may provide enhanced capacitance and electrical characteristics.

### PRIORITY STATEMENT

This application claims priority to Korean Patent Application No. 2007-70938, filed on Jul. 16, 2007, the contents of which are hereby incorporated by reference herein in their entirety.

### BACKGROUND

1. Technical Field

Example embodiments of the present invention relate to a capacitor, a method of manufacturing a capacitor, and a method of manufacturing a semiconductor device. More particularly, example embodiments of the present invention relate a capacitor including a lower electrode having a three-dimensional structure, a method of manufacturing the capacitor, and to a method of manufacturing a semiconductor device including the capacitor.

2. Description of the Related Art

Semiconductor memory devices are generally divided into volatile semiconductor memory devices and non-volatile semiconductor memory devices. The volatile semiconductor memory devices typically include dynamic random access memory (DRAM) devices, static random access memory (SRAM) devices, etc. The non-volatile semiconductor memory devices usually include electrically programmable read only memory (EPROM) devices, flash memory devices, electrically erasable and programmable read only memory (EEPROM) devices, etc.

The volatile semiconductor memory device may lose stored data when an applied power is off, whereas the non-volatile semiconductor memory device may maintain data stored therein even though an applied power goes off. The volatile semiconductor memory device may have a rapid response speed, a high integration degree, a low operation voltage, etc. Thus, a ferroelectric random access memory (FRAM) device has been developed because the FRAM device may provide the benefits of the non-volatile and the volatile semiconductor memory devices.

Generally, a ferroelectric material such as lead zirconium titanate [Pb(Zr, Ti)O₃; PZT], strontium bismuth tantalate (SrBi₂Ta₂O₉; SBT) or bismuth lanthanum titanate [(Bi, La)TiO₃; BLT] may have a large remanent polarization when an electric field applied to the ferroelectric material. Further, the orientation of polarization in the ferroelectric material may desirably vary in accordance with an applied voltage. The FRAM device including the ferroelectric material may have a construction substantially similar to that of the volatile semiconductor memory device such as the DRAM device whereas the FRAM device may have electrical characteristics substantially similar to those of the non-volatile semiconductor memory device. That is, the FRAM device may maintain stored data although an applied power goes off. Further, the FRAM device may provide a rapid response speed, a low operation voltage, a high integration degree, etc.

In a conventional FRAM device, a ferroelectric capacitor usually includes a lower electrode, a ferroelectric layer of a ferroelectric material and an upper electrode. As the conventional ferroelectric capacitor has a planar type, the ferroelectric layer is interposed between the lower electrode and the upper electrode.

As the design rule of the FRAM device is decreased, the capacitance of the planar type ferroelectric capacitor may also be considerably reduced. Thus, a ferroelectric capacitor having a cylindrical structure has been recently developed so as to provide improved capacitance.

In the cylindrical ferroelectric capacitor, a ferroelectric layer is formed on a cylindrical lower electrode. However, the ferroelectric layer positioned on an inside of the cylindrical lower electrode may be electrically deteriorated. For example, a portion of the ferroelectric layer on an upper portion of the cylindrical lower electrode may have a columnar crystalline structure, whereas a portion of the ferroelectric layer on the inside of the lower electrode may have particular crystalline structure.

When portions of the ferroelectric layer have the different crystalline structures, the entire ferroelectric and electrical characteristics of the ferroelectric layer may be considerably deteriorated, so that the electrical characteristics and capacitance of the ferroelectric capacitor may also be significantly reduced. Further, the ferroelectric layer may not be properly formed on the cylindrical lower electrode when the cylindrical lower electrode has a relatively high aspect ratio as the design rule of the FRAM device decreases. Accordingly, a ferroelectric capacitor having a novel structure for improving a capacitance may still be required to enhance electrical characteristics of an FRAM device.

### SUMMARY

Example embodiments of the present invention may provide a capacitor having a novel structure to provide improved capacitance and enhanced electrical characteristics.

Example embodiments of the present invention may provide a method of manufacturing a capacitor providing an improved capacitance and enhanced electrical characteristics.

Example embodiments of the present invention may provide a method of manufacturing a semiconductor device including a capacitor for providing an improved storage capacity and enhanced electrical characteristics.

In accordance with an example embodiment of the present invention, a capacitor is provided. The capacitor includes a lower electrode structure formed on a substrate, a ferroelectric layer pattern formed on the lower electrode structure, and an upper electrode structure formed on the ferroelectric layer pattern. The lower electrode structure includes an upper surface, a sidewall and a rounded surface between the upper surface and the sidewall. The ferroelectric layer pattern is formed on the upper surface, the sidewall and the rounded surface of the lower electrode structure.

In example embodiments, a conductive structure may be additionally provided on the substrate. An insulation layer may be disposed on the substrate to cover the conductive structure. A plug may be formed through the insulation layer. The plug may be electrically connected to the conductive structure. Here, the lower electrode structure may be positioned on the plug and the insulation layer.

In example embodiments, the lower electrode structure may include a first lower electrode on the substrate and a second lower electrode on the first lower electrode. The first lower electrode may include a metal compound, and the second lower electrode may include a metal, a metal compound and/or an alloy.

In example embodiments, the lower electrode structure may include a first lower electrode on the substrate, a second lower electrode formed on the first lower electrode and a third lower electrode on the second lower electrode. The first lower electrode may include doped polysilicon, a metal and/or a metal compound. The second lower electrode may include a metal compound, and the third lower electrode may include a metal, a metal compound and/or an alloy.

In example embodiments, a conductive structure may be further provided on the substrate. A first insulation layer may be disposed on the substrate to cover the conductive structure. A plug may be disposed through the first insulation layer. The plug may be electrically connected to the conductive structure. A second insulation layer may be provided on the plug and the first insulation layer. Here, a lower portion of the lower electrode structure may be buried in the second insulation layer.

In example embodiments, the lower electrode structure may include a first lower electrode on the plug and the first insulation layer and a second lower electrode on the first lower electrode. The second lower electrode may be partially buried in the second insulation layer. The first lower electrode may include a metal compound and the second lower electrode may include a metal, a metal compound and/or an alloy.

In example embodiments, the lower electrode structure may include a first lower electrode on the plug and the first insulation layer, and a second lower electrode on the first lower electrode and the second insulation layer. The first lower electrode may be partially buried in the second insulation layer. The first lower electrode may include doped polysilicon, a metal and/or a metal compound. The second lower electrode may include a metal compound. A third lower electrode may be further provided on the second lower electrode. The third lower electrode may include a metal, a metal compound and/or an alloy.

In example embodiments, the upper electrode structure may include a first upper electrode on the ferroelectric layer pattern, and a second upper electrode on the first upper electrode. The first upper electrode may include a metal compound and the second upper electrode may include a metal, a metal compound and/or an alloy.

In example embodiments, the sidewall of the lower electrode structure may be inclined by an angle of about 40° to about 80° relative to the substrate. Thus, the lower electrode structure may have an area gradually reduced in an upward direction.

In accordance with another example embodiment of the present invention, a method of manufacturing a capacitor is provided. In the method of manufacturing the capacitor, a lower electrode structure is formed on a substrate. The lower electrode structure has a sidewall, an upper surface and a rounded surface between the sidewall and the upper surface. A ferroelectric layer pattern is formed on the lower electrode structure. An upper electrode structure is formed on the ferroelectric layer pattern.

In example embodiments, a conductive structure may be provided on the substrate before forming the lower electrode structure. An insulation layer may be formed on the substrate to cover the conductive structure. A plug may be formed on the conductive structure through the insulation layer. Here, the lower electrode structure may be positioned on the plug and the insulation layer.

In the formation of the lower electrode structure according to example embodiments, a first lower electrode layer may be formed on the substrate, and then a second lower electrode layer may be formed on the first lower electrode layer. A preliminary lower electrode structure may be formed on the substrate by etching the first and the second lower electrode layers. The preliminary lower electrode structure may be partially etched to form the lower electrode structure including a first lower electrode and a second lower electrode. The first lower electrode layer may be formed using a metal compound, and the second lower electrode layer may be formed using a metal, a metal compound and/or an alloy. For example, the first lower electrode layer may be formed using titanium nitride, aluminum nitride, titanium aluminum nitride, tantalum nitride, tungsten nitride, titanium silicon nitride and/or tantalum silicon nitride. The second lower electrode layer may be formed using iridium, platinum, ruthenium, palladium, iridium oxide, ruthenium oxide, strontium ruthenium oxide and/or an alloy of iridium and ruthenium.

In example embodiments, the preliminary lower electrode structure and the lower electrode structure may be formed using an etching gas including a chlorine gas.

In example embodiments, the rounded surface of the lower electrode structure may be obtained by an etch-back process using argon ions.

In example embodiments, the ferroelectric layer pattern and the upper electrode structure may be formed by forming a ferroelectric layer on the lower electrode structure, by forming at least one upper electrode layer on the ferroelectric layer, and by etching the at least one upper electrode layer and the ferroelectric layer.

In the formation of the lower electrode structure according to example embodiments, a first lower electrode layer may be formed on the substrate. After a preliminary lower electrode structure may be provided by etching the first lower electrode layer, the preliminary lower electrode structure may be partially etched. A second lower electrode layer may be additionally formed on the etched preliminary lower electrode structure. A third lower electrode layer may be additionally formed on the second lower electrode layer. The third and the second lower electrode layers may be etched. Here, the first lower electrode layer may be formed using doped polysilicon, a metal and/or a metal compound. The second lower electrode layer may be formed using a metal compound, and the third lower electrode layer may be formed using a metal, a metal compound and/or an alloy.

In example embodiments, a first insulation layer may be formed on the substrate having a conductive structure. A plug may be formed through the first insulation layer. A first lower electrode layer may be formed on the plug and the first insulation layer. The first lower electrode layer may be etched to form a preliminary lower electrode structure. A second insulation layer may be formed on the first insulation layer to enclose a lower portion of the preliminary electrode structure. The preliminary lower electrode structure may be partially etched. A second lower electrode layer may be additionally formed on the second insulation layer to cover the etched preliminary lower electrode structure. A third lower electrode layer may be further formed on the second lower electrode layer. The third and the second lower electrode layers may be etched.

According to another example embodiment of the present invention, a method of manufacturing a semiconductor device is provided. In the method of manufacturing the semiconductor device, a conductive structure is provided on a substrate, and then an insulation layer covering the conductive structure is formed on the substrate. After a plug is formed through the insulation layer, a lower electrode structure is formed on the plug and the insulation layer. The plug is electrically connected to the conductive structure. The lower electrode structure includes a sidewall, an upper surface and a rounded surface between the sidewall and the upper surface. A ferroelectric layer pattern is formed on the lower electrode structure and an upper electrode structure formed on the ferroelectric layer pattern.

In example embodiments, the conductive structure may include a transistor having source/drain regions formed on the substrate.

In the formation of the lower electrode structure according to example embodiments, a first lower electrode layer may be formed on the plug and the insulation layer. The first lower electrode layer may be formed using a metal compound. A second lower electrode layer may be formed on the first lower electrode layer. The second lower electrode may be formed using a metal, a metal compound and/or an alloy. The second and the first lower electrode layers may be etched to form a preliminary lower electrode structure. The preliminary lower electrode structure may be partially etched to form the lower electrode structure including a first lower electrode and a second lower electrode.

In the formation of the lower electrode structure according to example embodiments, a first lower electrode layer may be formed on the plug and the insulation layer using a metal compound. A second lower electrode layer may be formed on the first lower electrode layer using a metal, a metal compound and/or an alloy. The second and the first lower electrode layers may be etched to form a preliminary lower electrode structure. A second insulation layer may be formed on the first insulation layer to enclose a lower portion of the preliminary lower electrode structure. The preliminary lower electrode structure may be partially etched.

In the formation of the lower electrode structure according to example embodiments, a first lower electrode layer may be formed on the plug and the insulation layer using doped polysilicon, a metal and/or a metal compound. The first lower electrode layer may be etched to form a preliminary lower electrode structure. A second insulation layer may be formed on the first insulation layer to enclose a lower portion of the preliminary lower electrode structure. A second lower electrode layer may be formed on the second insulation layer to cover the preliminary lower electrode structure using metal compound. A third lower electrode layer may be formed on the second lower electrode layer using a metal, a metal compound and/or an alloy. The third and the second lower electrode layers may be etched.

According to example embodiments of the present invention, the lower electrode structure of the capacitor may have the sidewall, the rounded surface and the upper surface, so that the effective area between the lower electrode structure and the ferroelectric layer pattern may be increased. Thus, the capacitor may have an improved capacitance. Further, the ferroelectric layer pattern may have a uniform crystalline structure because the ferroelectric layer pattern is provided on the lower electrode structure having the above-described construction. Accordingly, the capacitor including the lower electrode structure and the ferroelectric layer pattern may have enhanced electrical characteristics. When the capacitor is employed in a semiconductor device such as an FRAM device, the semiconductor device may provide improved electrical characteristics and enhanced storage capacity.

### BRIEF DESCRIPTION OF THE DRAWINGS

Example embodiments of the present invention can be understood in more detail from the following description taken in conjunction with the accompanying drawings, in which:

FIGS. 1 to 8 are cross-sectional views illustrating a method of manufacturing a semiconductor device including a capacitor in accordance with example embodiments of the present invention;

FIGS. 9 to 11 are cross-sectional views illustrating a method of manufacturing a semiconductor device having a capacitor in accordance with example embodiments of the present invention;

FIGS. 12 and 13 are cross-sectional views illustrating a method of manufacturing a semiconductor device having a capacitor in accordance with example embodiments of the present invention;

FIGS. 14 to 16 are cross-sectional views illustrating a method of manufacturing a semiconductor device including a capacitor in accordance with example embodiments of the present invention;

FIGS. 17 to 19 are cross-sectional views illustrating a method of manufacturing a semiconductor device including a capacitor in accordance with example embodiments of the present invention; and

FIGS. 20 to 22 are cross-sectional views illustrating a method of manufacturing a semiconductor device having a capacitor in accordance with example embodiments of the present invention;

### DESCRIPTION OF THE EXAMPLE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

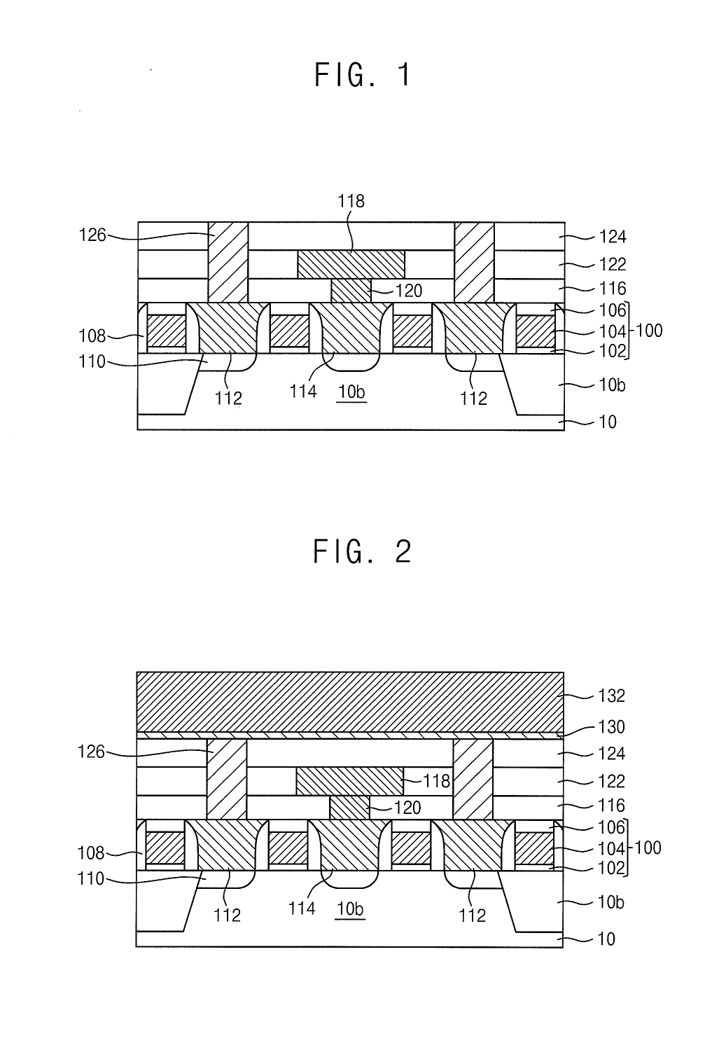

FIGS. 1 to 8 are cross-sectional views illustrating a method of manufacturing a semiconductor device including a capacitor in accordance with example embodiments of the present invention.

Referring to FIG. 1, conductive structures are provided on a substrate 10. The conductive structures may include a switching device such as a field effect transistor (FET).

The substrate 10 may include, for example, a silicon on insulator (SOI) substrate, a germanium on insulator (GOI) substrate, a metal oxide substrate or a semiconductor substrate such as a silicon (Si) substrate, a germanium (Ge) substrate, a silicon germanium substrate, etc.

In example embodiments, an isolation layer 10b is formed on the substrate 10 by an isolation process such as, for example, a thermal oxidation process or a shallow trench isolation (STI) process. The isolation layer 10b may include, for example, an oxide such silicon oxide. The isolation layer 10b may define an active region and a field region of the substrate 10.

A gate insulation layer is formed on the substrate 10, and then a gate conductive layer is provided on the gate insulation layer. The gate insulation layer may be formed using, for example, silicon oxide or metal oxide by a thermal oxidation process, a chemical vapor deposition (CVD) process, an atomic layer deposition (ALD) process, etc. The gate conductive layer may include, for example, doped polysilicon, a metal and/or a metal compound. The gate conductive layer may have a single layer structure or a multi layer structure.

After a gate mask 106 is provided on the gate conductive layer. The gate conductive layer and the gate insulation layer are etched to form a gate structure 100 on the substrate 10. The gate structure 100 includes a gate insulation layer pattern 102, a gate electrode 104 and the gate mask 106. The gate insulation layer pattern 102 and the gate electrode 104 may be formed by, for example, an anisotropic etching process. The gate mask 106 may be formed using a material that has an etching selectivity with respect to the gate conductive layer and the gate insulation layer. For example, the gate mask may include a nitride such as silicon nitride (SiNx) or an oxynitride such as silicon oxynitride (SiONx). Adjacent gate structures 100 may form a word line extending on the substrate 100.

In example embodiments, the gate mask 106, the gate electrode 104 and the gate insulation layer pattern 102 may be formed using, for example, a photoresist pattern as an etching mask. The photoresist pattern may be removed by, for example, an ashing process and/or a stripping process.

A spacer 108 is formed on a sidewall of the gate structure 100. In the formation of the spacer 108, a spacer formation layer may be formed on the substrate 10 to cover the gate structure 100. Then, the spacer formation layer is etched to provide the spacer 108 on the sidewall of the gate structure 100. The spacer formation layer may be formed using, for example, nitride or oxynitride. For example, the spacer formation layer may include, for example, silicon nitride or silicon oxynitride. The spacer 108 may be formed by, for example, an anisotropic etching process.

Source/drain regions 110 are formed at portions of the substrate 100 adjacent the gate structure 100. The source/drain regions 110 may be formed by, for example, an ion implantation process using the gate structure 100 as an implantation mask.

In example embodiments, the source/drain regions 110 may include lightly doped regions and heavily doped regions, respectively. Here, the lightly doped regions may be formed before forming the spacer 108, and the heavily doped regions may be provided after forming the spacer 108.

Referring now to FIG. 1, a first insulation layer is formed on the substrate 10 to cover the gate structure 100 and the source/drain regions 110. The first insulation layer may be formed using, for example, an oxide such as silicon oxide. For example, the first insulation layer may include boro-phosphor silicate glass (BPSG), phosphor silicate glass (PSG), spin on glass (SOG), undoped silicate glass (USG), flowable oxide (FOX), tetraethyl ortho silicate (TEOS), plasma enhanced-tetraethyl ortho silicate (PE-TEOS), high density plasma-chemical vapor deposition (HDP-CVD) oxide, etc. Further, the first insulation layer may be formed by, for example, a CVD process, a plasma enhanced chemical vapor deposition (PECVD) process, an HDP-CVD process, etc.

In example embodiments, the first insulation layer may be planarized by a planarization process. For example, an upper portion of the first insulation layer may be partially removed by a chemical mechanical polishing (CMP) process and/or an etch-back process. The first insulation layer may be planarized until the gate structure 100 is exposed.

After a photoresist pattern is formed on the first insulation layer, the first insulation layer is partially etched to form first contact holes through the first insulation layer. The first contact holes expose the source/drain regions 110, respectively. The first contact holes may be formed by, for example, an anisotropic etching process. After forming the first contact holes, the photoresist pattern may be removed from the first insulation layer by, for example, an ashing process and/or a stripping process.

A pad conductive layer is formed on the first insulation layer to fill up the first contact holes. The pad conductive layer may be formed using, for example, doped polysilicon, a metal and/or a metal compound. For example, the pad conductive layer may include tungsten (W), titanium (Ti), aluminum (Al), tantalum (Ta), tungsten nitride (WNx), aluminum nitride (AlNx), titanium nitride (TiNx), tantalum nitride (TaNx), etc. These may be used alone or in a mixture thereof. Additionally, the pad conductive layer may be formed by, for example, a sputtering process, a CVD process, an ALD process, an evaporation process, etc.

The pad conductive layer is removed until the first insulation layer is exposed to thereby provide first and second pads 112 and 114 in the first contact holes. Alternatively, the pad conductive layer may be removed until the gate structure 100 is exposed. Thus, the first and the second pads 112 and 114 make contact with the source/drain regions 110, respectively. The first and the second pads 112 and 114 may be formed by, for example, a CMP process and/or an etch-back process. The first pad 112 and the second pad 114 may electrically make contact with a ferroelectric capacitor and a bit line 118 successively formed.

A second insulation layer 116 is provided on the gate structure 100, the first pad 112 and the second pad 114. The second insulation layer 116 may be formed using, for example, an oxide such as silicon oxide. For example, the second insulation layer 116 may be formed using BPSG; PSG, SOG, USG, FOX, TEOS, PE-TEOS, HDP-CVD oxide, etc. The second insulation layer 116 may electrically insulate the first contact pad 112 from the bit line 118.

In example embodiments, the second insulation layer 116 may include an oxide substantially the same as that of the first insulation layer. Alternatively, the second insulation layer 116 may be formed using an oxide different from that of the first insulation layer.

After a photoresist pattern is provided on the second insulation layer 116, the second insulation layer 116 is partially etched using the photoresist pattern as an etching mask. Hence, a bit line contact hole exposing the second pad 114 is formed through the second insulation layer 116. The bit line contact hole may be formed by, for example, an anisotropic etching process. The photoresist pattern may be removed from the second insulation layer 116 by, for example, an ashing process and/or a stripping process.

A bit line conductive layer is formed on the second insulation layer 116 to fill the bit line contact hole, and then a bit line mask is provided on the bit line conductive layer. The bit line conductive layer may be formed using, for example, doped polysilicon, a metal and/or a metal compound. For example, the bit line conductive layer may be formed using titanium, tungsten, aluminum, tantalum, tungsten nitride, titanium nitride, aluminum nitride, etc. Additionally, the bit line conductive layer may be formed by, for example, an ALD process, a CVD process, a sputtering process, an evaporation process, a pulsed laser deposition (PLD) process, etc.

In example embodiments, the bit line conductive layer may include, for example, a first film of titanium/titanium nitride, and a second film of tungsten. The first film may serve as a barrier layer and an adhesion layer. The bit line mask may be formed using, for example, nitride or oxynitride.

Using the bit line mask as an etching mask, the bit line conductive layer is etched to provide the bit line 118 and a bit line pad 120. The bit line pad 120 is positioned in the bit line contact hole, and the bit line 118 is formed on the bit line pad 120 and the second insulation layer 116. The bit line 118 may electrically make contact with the source/drain regions 110 through the bit line pad 120 as the bit line pad 120 filling the bit line contact hole is formed on the source/drain regions 110. In example embodiments, the bit line mask and the bit line 118 may be formed by, for example, an anisotropic etching process using a photoresist pattern as an etching mask.

In example embodiments, a bit line spacer may be provided on a sidewall of the bit line 118. The bit line spacer may include, for example, a nitride such as silicon nitride or an oxynitride such as silicon oxynitride or titanium oxynitride. The bit line spacer may be formed by forming a bit line spacer formation layer covering on the second insulation layer 116, and by anisotropically etching the bit line spacer formation layer.

When the bit line spacer is formed on the sidewall of the bit line 118, a bit line structure may provide over the substrate 10. The bit line structure may include the bit line pad 120, the bit line 118, the bit line mask, and the bit line spacer.

A third insulation layer 122 is formed on the second insulation layer 116 to cover the bit line structure. The third insulation layer 122 may be formed using, for example, an oxide such as silicon oxide by a CVD process, a PECVD process, an HDP-CVD process, an ALD process, etc. For example, the third insulation layer 122 may include PSG, BPSG, SOG, USG, FOX, TEOS, PE-TEOS, HDP-CVD oxide, etc.

In example embodiments, the third insulation layer 122 may include substantially the same as that of the second insulation layer 116 and/or that of the first insulation layer. Alternatively, the first insulation layer, the second insulation layer 116 and the third insulation layer 122 may be formed using oxides different from one another.

The third insulation layer 122 may be planarized through, for example, a CMP process and/or an etch-back process. That is, an upper portion of the third insulation layer 122 may be partially removed to provide a level surface for the third insulation layer 122. In example embodiments, the third insulation layer 122 may be planarized until the bit line structure is exposed.

A fourth insulation layer 124 is provided on the third insulation layer 122. The fourth insulation layer 124 may be formed using an oxide such as, for example, silicon oxide by a CVD process, a PECVD process, an HDP-CVD process, an ALD process, etc. For example, the fourth insulation layer 124 may include PSG, BPSG, SOG, USG, FOX, TEOS, PE-TEOS, HDP-CVD oxide, etc.

The fourth insulation layer 124 may include substantially the same as that of the third insulation layer 122 that of the second insulation layer 116 and/or that of the first insulation layer. Alternatively, the first insulation layer, the second insulation layer 116, the third insulation layer 122 and the fourth insulation layer 124 may be formed using oxides different from one another.

In example embodiments, the third and the fourth insulation layers 122 and 124 may electrically insulate the bit line structure from the ferroelectric capacitor. Further, the third insulation layer 124 may also be planarized through, for example, a CMP process and/or an etch-back process, so that the fourth insulation layer 124 may have a level upper face.

A photoresist pattern is formed on the fourth insulation layer 124, the fourth, the third and the second insulation layers 124, 122 and 116 are partially etched using the photoresist pattern as an etching mask. The photoresist pattern may be removed from the fourth insulation layer 124 by, for example, an ashing process and/or a stripping process. Hence, a capacitor contact hole is provided through the second to the fourth insulation layers 116, 122 and 124. The capacitor contact hole may expose the first pad 112 positioned on the source/drain regions 110.

In example embodiments, a hard mask may be provided on the fourth insulation layer 124, and then the capacitor contact hole may be formed through the fourth to the second insulation layers 124, 122 and 116 using the hard mask as an etching mask. The hard mask may include, for example, silicon nitride, silicon oxynitride, etc. The capacitor contact hole may be obtained by, for example, an anisotropic etching process.

A plug conductive layer is formed on the fourth insulation layer 124 to fill the capacitor contact hole. The plug conductive layer may be formed using, for example, a metal, a metal compound and/or polysilicon doped with impurities. For example, the plug conductive layer may include titanium, aluminum, tungsten, tantalum, titanium nitride, tungsten nitride, aluminum nitride, etc. The plug conductive layer may be formed by, for example, a CVD process, an ALD process, an evaporation process, a PLD process, a sputtering process, etc.

In example embodiments, the plug conductive layer may include, for example, a third film of titanium/titanium nitride, and a fourth film of tungsten. The third film may also serve as a barrier layer and an adhesion layer.

The plug conductive layer is partially removed until the fourth insulation layer 124 is exposed, so that a plug 126 is formed in the capacitor contact hole. As the plug 126 is positioned on the first pad 112, the plug 126 may be electrically connected to the source/drain regions 110 through the first pad 112.

Referring to FIG. 2, a first lower electrode layer 130 and a second lower electrode layer 132 are formed on the plug 126 and the fourth insulation layer 126. The second lower electrode layer 132 may have a thickness substantially larger than that of the first lower electrode layer 130.

The first lower electrode layer 130 may be formed using, for example, a metal compound. For example, the first lower electrode layer 130 may include titanium nitride, aluminum nitride, titanium aluminum nitride (TiAlNx), tungsten nitride, tantalum nitride, titanium silicon nitride (TiSiNx), tantalum silicon nitride (TaSiNx), etc. These may be used alone or in a mixture thereof. Further, the first lower electrode layer 130 may be formed by, for example, a CVD process, a sputtering process, an ALD process, an evaporation process, a PLD process, etc.

The first lower electrode layer 130 may have a relatively thickness of about 50 Å to about 500 Å measured from the upper face of the fourth insulation layer 126. In example embodiments, the first lower electrode layer 130 may be formed by, for example, the sputtering process using titanium aluminum nitride. The first lower electrode layer 130 may serve as an adhesion layer and a diffusion barrier layer. For example, the first lower electrode layer 130 may prevent oxygen atoms in a ferroelectric layer 148 (see FIG. 6) from diffusing toward underlying structures.

The second lower electrode layer 132 may be formed, for example, using a metal, a metal compound and/or an alloy. For example, the second lower electrode layer 132 may include iridium (Ir), ruthenium (Ru), platinum (Pt), palladium (Pd), iridium oxide (IrOx), ruthenium oxide (RuOx), strontium ruthenium oxide (SrRuOx), iridium-ruthenium alloy, etc. These may be used alone or in a mixture thereof. Additionally, the second lower electrode layer 132 may be formed by, for example, a CVD process, an ALD process, a sputtering process, a PLD process, an evaporation process, etc.

The second lower electrode layer 132 may have a relatively thickness of about 1,000 Å to about 2,500 Å measured from an upper face of the first lower electrode layer 130. In example embodiments, the second lower electrode layer 132 may be formed by, for example, the sputtering process using iridium. Alternatively, the second lower electrode layer 132 may have a multi layer structure that includes a metal oxide film and a metal film. For example, the second lower electrode layer 132 may include a strontium ruthenium oxide film and an iridium film, or an iridium oxide film and an iridium film.

A first hard mask layer is provided on the second lower electrode layer 132. The first hard mask layer may be formed using, for example, a nitride such as silicon nitride or an oxynitride such as silicon oxynitride. The first hard mask layer may have a thickness of about 500 Å to about 1,500 Å based on an upper face of the second lower electrode layer 132.

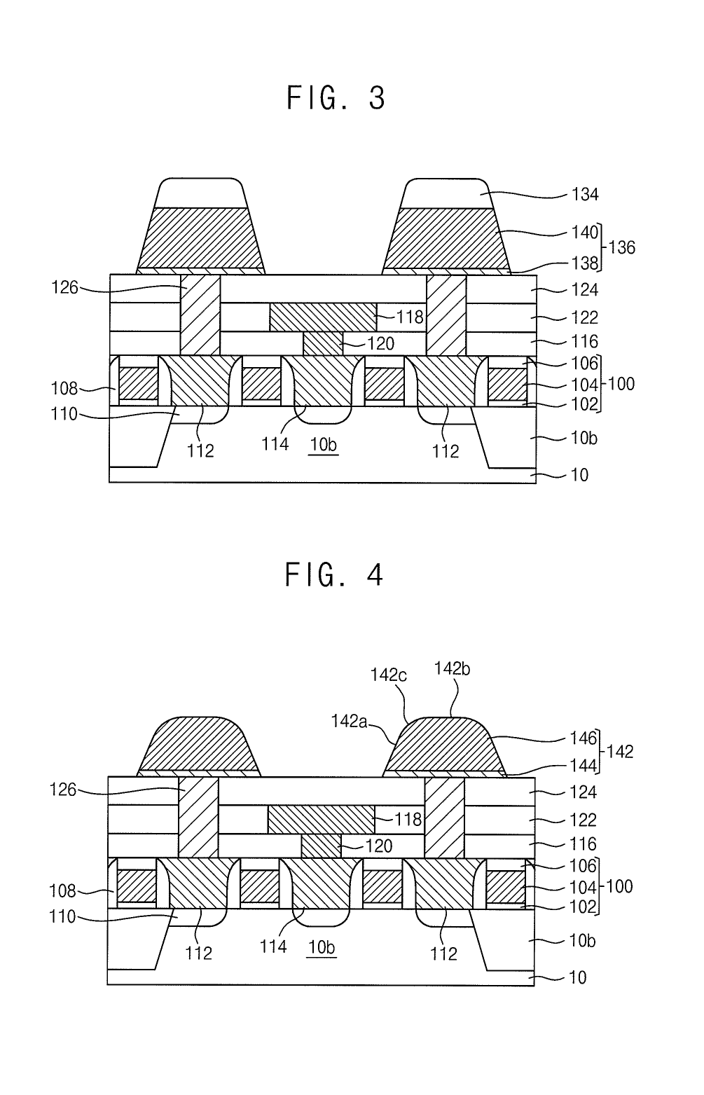

Referring to FIG. 3, a photoresist pattern is provided on the first hard mask layer, and then a first hard mask 134 is formed on the second lower electrode layer 132 by etching the first hard mask layer using the photoresist pattern an etching mask. The first hard mask 134 may be formed through, for example, an anisotropic etching process. After forming the first hard mask 134, the photoresist pattern may be removed by, for example, an ashing process and/or a stripping process.

A preliminary lower electrode structure 134 is formed on the plug 126 and the fourth insulation layer 124 by patterning the first and the second lower electrode layers 138 and 140. The preliminary lower electrode structure 134 may be formed by, for example, an anisotropic etching process. The preliminary lower electrode structure 134 includes a first lower electrode layer pattern 138 and a second lower electrode layer pattern 140. The first hard mask 134 may be partially consumed in an etching process for forming the preliminary lower electrode structure 136.

In example embodiments, the preliminary lower electrode structure 136 may have a sidewall inclined by a first angle. For example, the preliminary lower electrode structure 136 may be inclined by a first angle of about 70° to about 80° with respect to the substrate 10. Thus, the preliminary lower electrode structure 136 may have an upper portion substantially smaller that a power portion thereof. Further, the first lower electrode layer pattern 138 may have an area substantially larger than that of the second lower electrode layer pattern 140.

In example embodiments, the preliminary lower electrode structure 136 may be formed using, for example, an etching gas that includes a chlorine gas and an oxygen gas. Here, the etching gas may additionally include, for example, an argon gas. The etching gas may have a plasma state by applying a radio frequency (RF) power of about 700 W to about 1,200 W to the etching gas.

The first and the second lower electrode layer patterns 138 and 140 may be provided using the etching gas and/or the plasma generated from the etching gas. The first hard mask 134 may be removed after forming the preliminary lower electrode structure 136 on the plug 126 and the fourth insulation layer 124. Alternatively, the first hard mask 134 may be consumed in the etching process for forming the preliminary lower electrode structure 136.

Referring to FIG. 4, a lower electrode structure 142 is formed from the preliminary lower electrode structure 136 by partially etching the preliminary lower electrode structure 136. The lower electrode structure 142 may be formed, for example, using an etching gas including an argon gas. The lower electrode structure 142 includes a first lower electrode 144 and a second lower electrode 146. The first lower electrode 144 is positioned on the plug 126 and the fourth insulation layer 124, and the second lower electrode 146 is provided on the first lower electrode 144.

In example embodiments, edge and sidewall portions of the preliminary lower electrode structure 136 are partially removed to form the lower electrode structure 142. The lower electrode structure 142 may include a sidewall 142a, an upper surface 142b and a rounded surface 142c. The sidewall 142a of the lower electrode structure 142 may be inclined by a second angle substantially the same as or substantially smaller than the first angle of the sidewall of the preliminary lower electrode structure 136, The rounded surface 142c may be located between the sidewall 142a and the upper surface 142b. The lower electrode structure 142 may also have an upper portion substantially smaller than a lower portion thereof. Namely, an area of the lower electrode structure 142 may be gradually reduced in an upward direction.

In example embodiments, the second angle of the lower electrode structure 142 may be adjusted by controlling a bias power applied to a chuck that supports the substrate 10. For example, the sidewall of the lower electrode structure 142 may have the second angle of about 60° to about 80° relative to the substrate 10.

The lower electrode structure 142 may be formed, for example, using an etching including an argon gas, a chlorine gas and an oxygen gas. Here, the chlorine gas and the oxygen gas may control a radius of curvature of an edge portion of the lower electrode structure 142. Further, the chlorine gas and the oxygen gas may adjust the second angle of the sidewall 142a of the lower electrode structure 142.

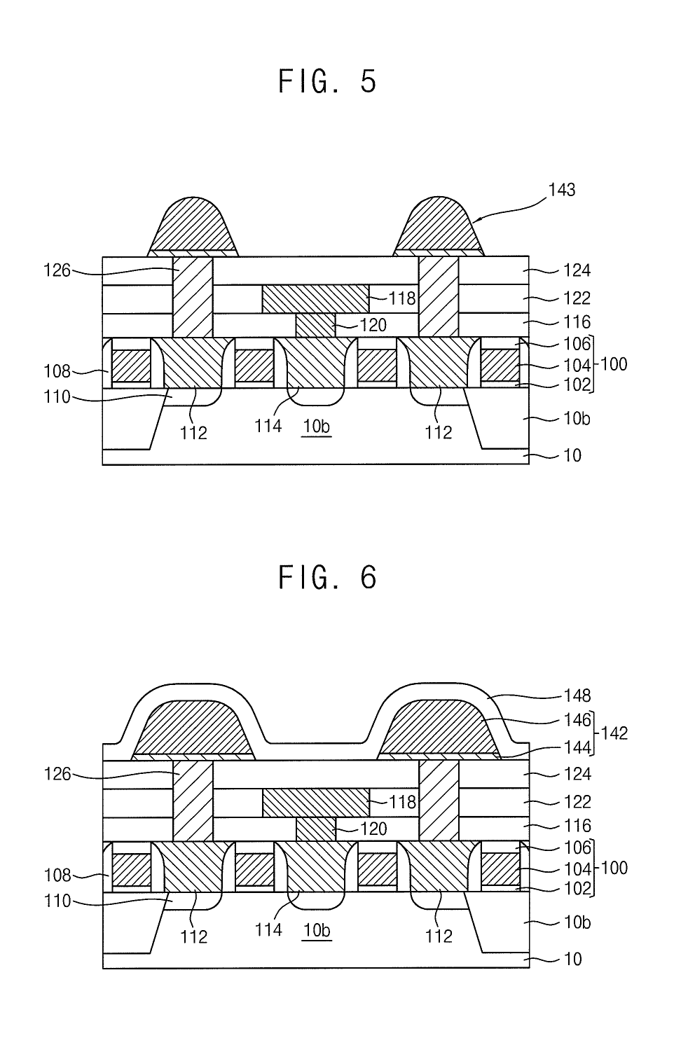

In example embodiments, a lower electrode structure 143 may have a dome shape or a cone shape as illustrated in FIG. 5. Here, the lower electrode structure 143 may include a rounded upper portion. For example, a second lower electrode of the lower electrode structure 143 may include an upper portion having a rounded edge portion. However, the shape of the lower structures 142 and 143 may vary in accordance with dimensions and shape of the first hard mask 134, process conditions of the etching process for forming the preliminary lower electrode structure 136 and/or process conditions of the etching processes for forming the lower electrode structures 142 and 143.

Referring to FIGS. 4 and 6, a ferroelectric layer 148 is formed on the fourth insulation layer 124 to cover the lower electrode structure 142. The ferroelectric layer 148 may have a thickness of about 200 Å to about 1,200 Å. The ferroelectric layer 148 may be formed, for example, using a ferroelectric material such as barium titanate (BaTiO₃), lead zirconate titanate [Pb(Zr, Ti)O₃; PZT], strontium bismuth tantalate (SrBi₂Ta₂O₉; SBT), bismuth lanthanum titanate [(Bi, La)TiO₃; BLT], lanthanum-doped lead zirconium titanate [Pb(La, Zr)TiO₃; PLZT], barium strontium titanate [(Bi, Sr)TiO₃; BST], etc Alternatively, the ferroelectric layer 148 may be formed, for example, using a ferroelectric material doped with a metal. For example, the ferroelectric layer 148 may include, for example, the above-mentioned ferroelectric material doped with calcium (Ca), lanthanum (La), manganese (Mn), bismuth (Bi), etc.

The ferroelectric layer 148 may be formed by, for example, a metalorganic chemical vapor deposition (MOCVD) process, a sol-gel process, a liquid phase epitaxy (LPE) process, an ALD process, etc. In example embodiments, the ferroelectric layer 148 may be formed by, for example, the MOCVD process using PZT.

In example embodiments, the ferroelectric layer 148 may have a desired crystalline structure including uniform column-shaped grains because the lower electrode structure 142 has the rounded edge portion and the sidewall 142a of the second angle. Accordingly, the ferroelectric layer 148 may have improved electrical characteristics. Further, an effective area of the ferroelectric capacitor may be increased as the ferroelectric layer 148 may be continuously formed the sidewall 142a, the rounded surface 142c and the upper surface 142a of the lower electrode structure 142. As a result, the ferroelectric capacitor may have enhanced capacitance and electrical characteristics.

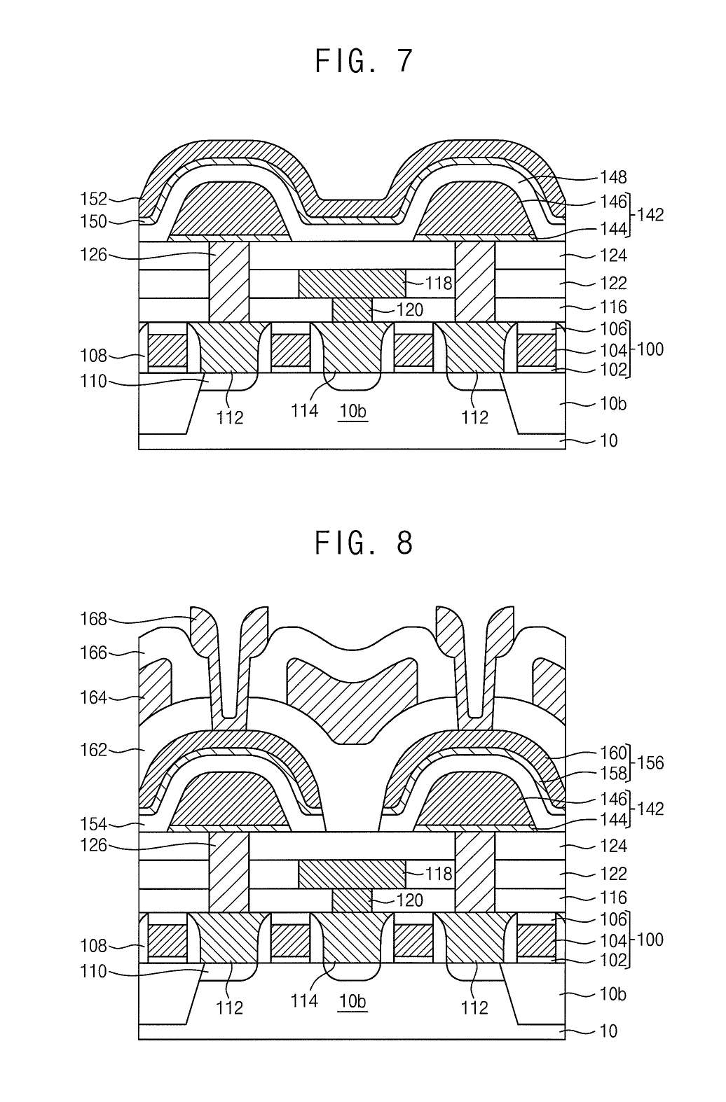

Referring to FIG. 7, a first upper electrode layer 150 and a second upper electrode layer 152 are formed on the ferroelectric layer 148. The second upper electrode layer 152 may have a thickness substantially larger than that of the first upper electrode layer 150.

The first upper electrode layer 150 may have a relatively thin thickness of about 10 Å to about 300 Å measured from an upper face of the ferroelectric layer 148. The first upper electrode layer 150 may be formed using a metal compound. For example, the first upper electrode layer 150 may include indium tin oxide (In₂Sn₂O₇; ITO), iridium oxide (IrO₂), strontium ruthenium oxide (SrRuO₃; SRO), strontium titanium oxide (SrTiO₃; STO), lanthanum nickel oxide (LnNiO₃; LNO), calcium ruthenium oxide (CaRuO₃; CRO), etc. Additionally, the first upper electrode layer 150 may be formed by, for example, an electron beam evaporation process, a sputtering process, a CVD process, an ALD process, a PLD process, etc. In example embodiments, the first upper electrode layer 150 may be formed by, for example, the sputtering process using strontium ruthenium oxide (SRO).

The second upper electrode layer 152 may be formed using, for example, a metal, an alloy, a metal compound, etc. For example, the second upper electrode layer 152 may include iridium, ruthenium, platinum, palladium, iridium oxide, ruthenium oxide, strontium ruthenium oxide (SRO), an alloy of iridium-ruthenium, an alloy of iridium-platinum, an alloy of ruthenium-platinum, etc.

When the second upper electrode layer 152 includes the alloy of iridium-ruthenium, the second upper electrode layer 152 may include about 30 to about 50 atomic weight percent of iridium and about 50 to about 70 atomic weight percent of ruthenium. Here, the content ratio between iridium and the ruthenium may be in a range of about 1.0:1.0 to about 1.0:1.4. For example, the second upper electrode layer 152 may include about 40 atomic weight percent of iridium and about 60 atomic weight percent of ruthenium.

In example embodiments, the second upper electrode layer 152 may be formed using, for example, a first target of iridium and a second target of ruthenium in the sputtering process. The content ratio between iridium and ruthenium may be adjusted by controlling powers applied to the first and the second targets.

The second upper electrode layer 152 may be formed on the first upper electrode layer 150 by, for example, an evaporation process, a sputtering process, a CVD process, an ALD process, a PLD process, etc. The second upper electrode layer 152 may have a relatively thick thickness of about 300 Å to about 1,000 Å based on an upper face of the first upper electrode layer 150.

In example embodiments, a thermal treatment process may be performed about the first upper electrode layer 150 so as to prevent the volatilization of metal ingredients from the first upper electrode layer 150. Additionally, the damage to the second upper electrode layer 152 generated in the sputtering process may be cured in the thermal treatment process. The thermal treatment process may include, for example, a rapid thermal process. For example, the thermal treatment process may be carried out at a temperature of about 500° C. to about 700°. Further, the thermal treatment process may be executed under an oxygen atmosphere and/or a nitrogen atmosphere.

Referring to FIG. 8, a second hard mask layer is formed on the second upper electrode layer 152. The second hard mask layer is etched to provide a second hard mask on the second upper electrode layer 152 by, for example, a photolithography process. The second hard mask may be formed through, for example, an anisotropic etching process.

Using the second hard mask as an etching mask, the second upper electrode layer 152, the first upper electrode layer 150 and the ferroelectric layer 148 are partially etched to form a ferroelectric layer pattern 154 and an upper electrode structure 156 on the lower electrode structure 142. The upper electrode structure 156 includes a first upper electrode 158 and a second upper electrode 160 sequentially formed on the ferroelectric layer pattern 154. As a result, the ferroelectric capacitor including the lower electrode structure 142, the ferroelectric layer pattern 154 and the upper electrode structure 156 is provided on the plug 126 and the fourth insulation layer 124.

The ferroelectric capacitor may be electrically connected to the source/drain regions 110 through the first pad 112 and the plug 126. As the lower electrode structure 142 of the ferroelectric capacitor includes the sidewall 142a, the upper surface 142b and the rounded surface 142c, the ferroelectric capacitor may have considerably improved capacitance and electrical characteristics.

A fifth insulation layer 162 is formed on the fourth insulation layer 124 to cover the ferroelectric capacitor. The fifth insulation layer 162 may be formed using, for example, an oxide such as BPSG, PSG SOG, USG, FOX, TEOS, PE-TEOS, HDP-CVD oxide, etc.

A first wiring 164 is provided on the fifth insulation layer 162, and then a sixth insulation layer 166 is formed on the fifth insulation layer 162 to cover the first wiring 164. The first wiring 164 may be formed using, for example, a metal, doped polysilicon and/or a metal compound. For example, the first wiring 164 may include copper (Cu), aluminum, tungsten, titanium, tungsten nitride, titanium nitride, aluminum nitride, etc. Further, the first wiring 164 may be formed by, for example, a CVD process, an ALD process, a sputtering process, an evaporation process, a PLD process, etc. The sixth insulation layer 166 may include, for example, an oxide such as BPSG, PSG SOC, USG, FOX, TEOS, PE-TEOS, HDP-CVD oxide, etc.

A second wiring 168 is formed on the sixth insulation layer 166. The second wiring 168 may be formed using, for example, doped polysilicon, a metal and/or a metal compound. For example, the second wiring 168 may include copper, aluminum, tungsten, titanium, tungsten nitride, titanium nitride, aluminum nitride, etc. The second wiring 168 may also be formed by, for example, a CVD process, an ALD process, a sputtering process, an evaporation process, a PLD process, etc. The second wiring 168 makes contact with the upper electrode structure 156 through the sixth and the fifth insulation layers 162 and 166.

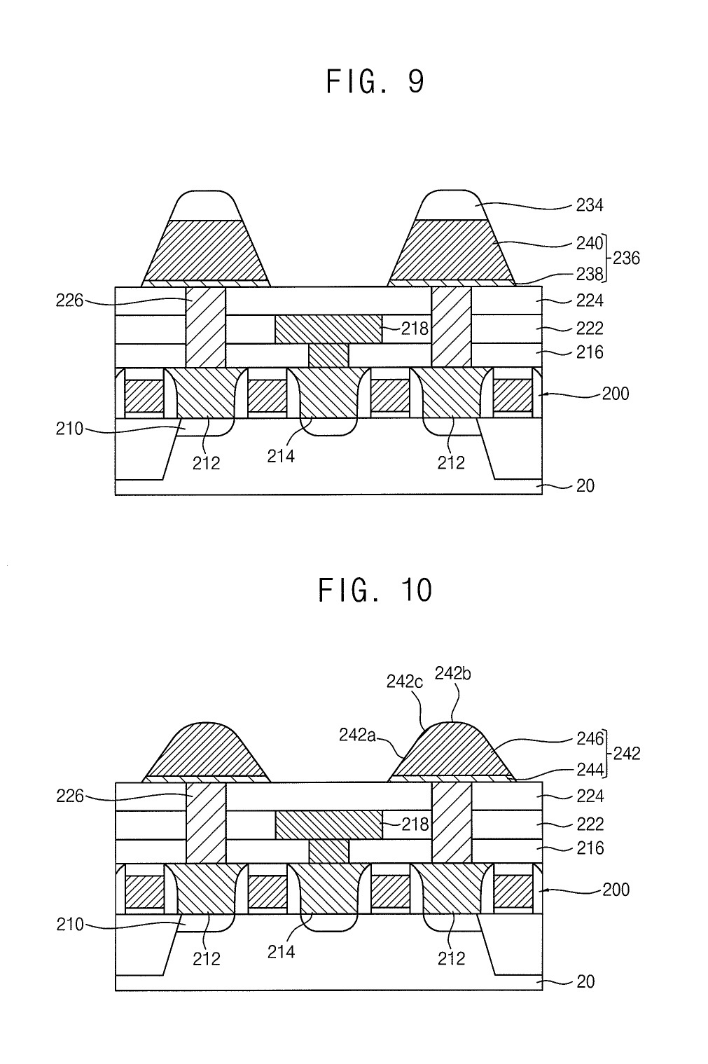

FIGS. 9 to 11 are cross-sectional views illustrating a method of manufacturing a semiconductor device having a capacitor in accordance with example embodiments of the present invention.

Referring to FIG. 9, after a conductive structure 200 including a switching device is provided on a substrate 20, source/drain regions 210 are formed at portions of the substrate 20 adjacent to the conductive structure 200. The conductive structure 200 may include a FET. Here, the conductive structure 200 may be formed by processes substantially similar to those described with reference FIG. 1.

A first insulation layer covering the conductive structure 200 is formed on the substrate 200, and then first and second pads 212 and 214 are formed through the first insulation layer. The first and the second pads 212 and 214 make electrical contact with the source/drain regions 210.

A second insulation layer 216 is formed on first pad 212, the second pad 214 and the first insulation layer. A bit line 218 is formed on the second insulation layer 216. The bit line 218 extends to the second pad 214 through the first insulation layer.

After a third insulation layer 222 is formed on the second insulation layer 216, a fourth insulation layer 224 covering the bit line 218 is provided on the third insulation layer 222.

A plug 226 is formed through the fourth insulation layer 224, the third insulation layer 222 and the second insulation layer 216. The plug 226 is electrically connected to the source/drain regions 210 through the first pad 212.

A first lower electrode layer and a second lower electrode layer are formed on the plug 226 and the fourth insulation layer 224. The first lower electrode layer may include a metal compound and the second lower electrode layer may include, for example, a metal, a metal compound and/or an alloy.

A photoresist pattern 234 is provided on the second lower electrode layer, and then the second and the first lower electrode layers are patterned using the photoresist pattern 234 as an etching mask. Thus, a preliminary lower electrode structure 236 is formed on the fourth insulation layer 224 centering the plug 226. The preliminary lower electrode structure 236 may be formed by, for example, an anisotropic etching process. The preliminary lower electrode structure 236 includes a first lower electrode layer pattern 238 and a second lower electrode layer pattern 240.

In the formation of the preliminary lower electrode structure 236, the photoresist pattern 234 may be considerably consumed in comparison with the first hard mask 134, so that the preliminary lower electrode structure 236 may include an inclined sidewall by a third angle substantially smaller than the first angle. For example, the sidewall of the preliminary lower electrode structure 236 may be inclined by about 50° to about 70° relative to the substrate 20.

In example embodiments, the preliminary lower electrode structure 236 may be formed using, for example, an etching gas that includes a chlorine gas and an oxygen gas. Further, the etching gas may include, for example, an argon gas. The etching gas may have a plasma state by applying an RF power of about 700 W to about 1,299 W to the etching gas.

The first and the second lower electrode layers may be etched by the plasma, chlorine ions and oxygen ions. The photoresist pattern 234 may be removed from the preliminary lower electrode structure 236 by, for example, an ashing process and/or a stripping process.

Referring to FIG. 10, the preliminary lower electrode structure 236 is partially etched to form a lower electrode structure 242 on the plug 226 and the fourth insulation layer 224. The lower electrode structure 242 includes a first lower electrode 244 and a second lower electrode 246. The lower electrode structure 242 may be formed by, for example, partially etching the first and the second lower electrode layers 238 and 240 using argon ions. For example, an edge portion and a sidewall of the preliminary lower electrode structure 236. Thus, the lower electrode structure 242 has a sidewall 242a, an upper surface 242b and a rounded surface 242c between the sidewall 242a and the upper surface 242b.

The sidewall 242a of the lower electrode structure 242 may be inclined by a fourth angle substantially smaller than the third angle of the sidewall of the preliminary lower electrode structure 236. Accordingly, an area of the lower electrode structure 242 may be gradually reduced along an upward direction. For example, the lower electrode structure 242 may have a dome shape, a cone shape, etc.

In example embodiments, the lower electrode structure 242 may be formed by, for example, an etch-back process. In the etch-back process, the fourth angle of the sidewall 242a of the lower electrode structure 242 may be properly adjusted by controlling a bias power applied to a chuck for supporting the substrate 20. For example, the sidewall 242a of the lower electrode structure 242 may have the fourth angle of about 40° to about 70° with respect to the substrate 20. An etching gas including, for example, a chlorine gas and an oxygen gas may be additionally provided onto the substrate 20 in the formation of the lower electrode structure 242. The etching gas may desirably adjust the fourth angle of the sidewall 242a and a radius of curvature of an edge portion of the lower electrode structure 242.

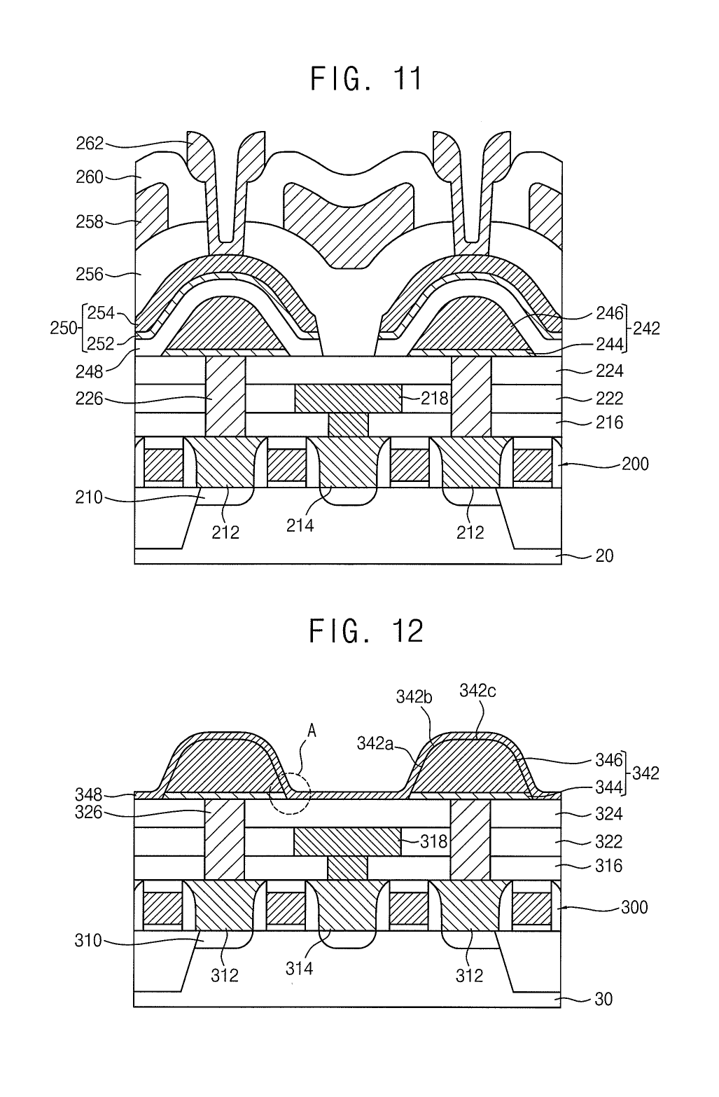

Referring to FIG. 11, a ferroelectric layer is formed on the fourth insulation layer 224 and the lower electrode structure 242. The ferroelectric layer may be formed using, for example, a ferroelectric material or a ferroelectric material doped with metal. Additionally, the ferroelectric layer may be formed by, for example, a MOCVD process, a sol-gel process, an LPE process, an ALD process, etc.

A first upper electrode layer and a second upper electrode layer are provided on the ferroelectric layer. The first and the second upper electrode layers may be formed using, for example, a metal compound, a metal, an alloy, etc. Further, the first and the second upper electrode layers may be independently formed by, for example, a CVD process, an ALD process, a sputtering process, a PLD process, an evaporation process, etc.

After a hard mask is formed on the second upper electrode layer, the second upper electrode layer, the first upper electrode layer and the ferroelectric layer are partially etched. Hence, a ferroelectric layer pattern 248 and an upper electrode structure 250 are provided on the lower electrode structure 242 and the fourth insulation layer 224. The upper electrode structure 250 includes a first upper electrode 252 and a second upper electrode 254 successively formed on the ferroelectric layer pattern 248. Accordingly, a ferroelectric capacitor is formed over the substrate 20. The ferroelectric capacitor includes the lower electrode structure 242, the ferroelectric layer pattern 248 and the upper electrode structure 250.

As described above, the ferroelectric capacitor may have enhanced capacitance and electrical characteristics because the lower electrode structure includes the inclined sidewall 242a and the rounded surface 242c, and the ferroelectric layer pattern 248 covers the lower electrode structure 242 on the fourth insulation layer 224.

A first wiring 258 is formed on a fifth insulation layer 256 after the fifth insulation layer 256 is formed on the fourth insulation layer 224 to cover the ferroelectric capacitor. For example, the first wiring 258 may be formed using a metal and/or a metal compound by a CVD process, an ALD process, a sputtering process, an evaporation process, a PLD process, etc.

A sixth insulation layer 260 covering the first wiring 258 is formed on the fifth insulation layer 256, and then the sixth and the fifth insulation layers 258 and 256 are partially etched to form an opening that exposes the upper electrode structure 250.

A second wiring 262 is formed on the sixth insulation layer 260 to partially fill the opening. Thus, the second wiring 262 makes electrical contact with the upper electrode structure 250 of the ferroelectric capacitor. The second wiring 262 may be formed using, for example, a metal and/or a metal compound by a CVD process, an ALD process, a sputtering process, an evaporation process, a PLD process, etc.

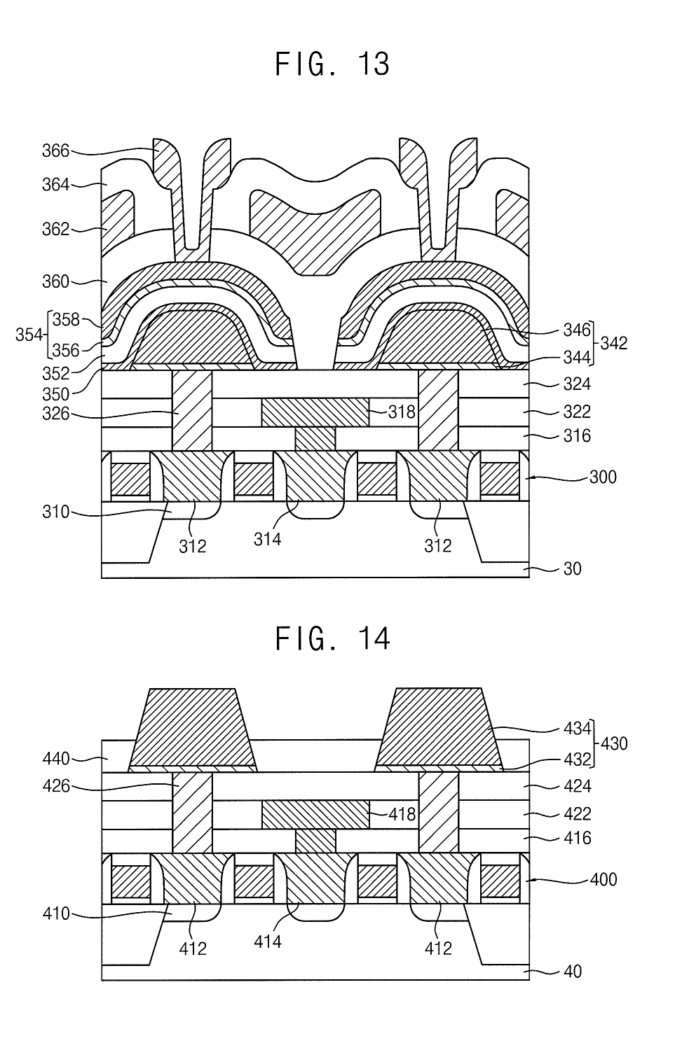

FIGS. 12 and 13 are cross-sectional views illustrating a method of manufacturing a semiconductor device having a capacitor in accordance with example embodiments of the present invention.

Referring to FIG. 12, a conductive structure 300 having source/drain regions 310 such as a transistor is formed on a substrate 30. Then, a first insulation layer is on the substrate 30 to cover the conductive structure 300.

A first pad 312 and a second pad 314 are formed through the first insulation layer. The first and the second pads 312 and 314 may electrically contact with the source/drain regions 310, respectively.

A second insulation layer 316 is formed on the first pad 312, the second pad 314 and the first insulation layer. A bit line 318 extending to the second pad 314 is formed on the second insulation layer 316.

A third insulation layer 322 is provided on the second insulation layer 316. The bit line 318 is buried in the third insulation layer 322. A fourth insulation layer 324 is formed on the bit line 318 and the third insulation layer 322.

A plug 326 passing through the fourth, the third and the second insulation layers 324, 322 and 316 is formed on the first pad 312. The plug 326 makes electrical contact with the source/drain regions 310 through the first pad 312.

A first lower electrode 344 is formed on the plug 326 and the fourth insulation layer 324. A second lower electrode 346 is provided on the first lower electrode 344. For example, first lower electrode 344 may include a metal compound and the second lower electrode 346 may include a metal, a metal compound and/or an alloy.

The first lower electrode 344 and the second lower electrode 346 are formed by etching a first lower electrode layer and a second lower electrode layer after sequentially forming the first and the second lower electrode layers on the plug 326 and the fourth insulation layer 324.

In example embodiments, a first hard mask may be provided on the second lower electrode layer so as to etch the second and the first lower electrode layers. As the second lower electrode 346 has an inclined sidewall, an upper surface and a rounded surface between the sidewall and the upper face, the lower electrode structure 342 also includes an inclined sidewall 342a, an upper surface 342b and a rounded surface 342c between the sidewall 342a and the upper surface 342b.

In example embodiments, a third lower electrode layer 348 is formed on the fourth insulation layer 324 to cover the first and the second lower electrodes 344 and 346. The third lower electrode layer 348 may improve the uniformity of the crystalline structure in a ferroelectric layer. For example, the third lower electrode layer 348 may improve the profiles of lower edge portions A of the first and the second lower electrodes 344 and 346 positioned on the fourth insulation layer 324.

The third lower electrode layer 348 may be formed using, for example, a metal, a metal compound and/or an alloy. For example, the third lower electrode layer 348 may be formed using iridium, ruthenium, platinum, palladium, iridium oxide, ruthenium oxide, strontium ruthenium oxide, iridium-ruthenium alloy, etc. These may be used alone or in a mixture thereof. Further, the third lower electrode layer 348 may be formed by, for example, a sputtering process, a CVD process, an ALD process, an evaporation process, a PLD process, etc.

The third lower electrode layer 348 may have a relatively thin thickness of about 50 Å to about 150 Å. The third lower electrode layer 348 may include a material substantially the same as or substantially similar to that of the second lower electrode 346. Alternatively, the third lower electrode layer 348 may include a material different from that of the second lower electrode 346.

Referring to FIG. 13, the ferroelectric layer is formed on the third lower electrode layer 348, and then a first upper electrode layer and a second upper electrode layer are provided on the ferroelectric layer.

After forming a second hard mask is formed on the second upper electrode layer, the second upper electrode layer, the first upper electrode layer, the ferroelectric layer and the third lower electrode layer 348 are etched to form a ferroelectric capacitor over the substrate. The ferroelectric capacitor has the lower electrode structure 342, a ferroelectric layer pattern 352 and an upper electrode structure 354.

As the third lower electrode layer 348 is patterned to form a third lower electrode 350, the lower electrode structure 342 includes the first, the second and the third lower electrodes 344, 346 and 350. Here, the third lower electrode 350 covers the second lower electrode 346 and extends on the fourth insulation layer 324. The upper electrode structure 354 includes a first upper electrode 356 and a second upper electrode 358 formed by etching the first upper electrode layer and the second upper electrode layer, respectively.

A fifth insulation layer 360 is formed on the fourth insulation layer 324 to cover the upper electrode structure 354, and a first wiring 362 is provided on the fifth insulation layer 360. The first wiring 362 may be positioned on a portion of the fifth insulation layer 360 between adjacent ferroelectric capacitors.

A sixth insulation layer 364 covering the first wiring 363 is provided on the fifth insulation layer 360. The sixth and the fifth insulation layers 364 and 360 are partially etched to provide an opening that exposes the upper electrode structure 354 of the ferroelectric capacitor.

A second wiring 366 contacting the upper electrode structure 354 is formed on the sixth insulation layer 364 and a sidewall of the opening. The second wiring 366 may partially fill up the opening.

FIGS. 14 to 16 are cross-sectional views illustrating a method of manufacturing a semiconductor device having a capacitor in accordance with example embodiments of the present invention.

Referring to FIG. 14, a conductive structure 400 including a switching device is formed on a substrate 40. The conductive structure 400 may include an FET. Source/drain regions 410 are provided on the substrate 40. A first insulation layer is formed on the substrate 40, and then a first pad 412 and a second pad 414 are formed through the first insulation layer.

A second insulation layer 416 is formed on the first insulation layer, and a bit line 418 extending to the second pad 414 is formed through the second insulation layer 416. A third insulation layer 422 is provided on the bit line 418 and the second insulation layer 422, and then a fourth insulation layer 424 is formed on the third insulation layer 422. A plug 426 is formed through the fourth, the third and the second insulation layers 424, 422 and 416. The plug 426 is located on the first pad 412.

A first lower electrode layer and a second lower electrode layer are formed on the plug 326 and the fourth insulation layer 424. The first lower electrode layer may include, for example, a metal compound, and the second lower electrode layer may include, for example, a metal, a metal compound and/or an alloy.

After a first hard mask is provided on the second lower electrode layer, the second and the first lower electrode layers are etched to thereby form a preliminary lower electrode structure 430 having a first electrode layer pattern 432 and a second electrode layer pattern 434 over the substrate 40. The first lower electrode layer pattern 432 is formed on the plug 426 and the fourth insulation layer 424, and the second lower electrode layer pattern 434 is positioned on the first lower electrode layer pattern 432.

A preliminary fifth insulation layer is formed on the fourth insulation layer 424 to cover the preliminary lower electrode structure 430. The preliminary fifth insulation layer is partially removed until an upper portion of the preliminary lower electrode structure 430 is exposed. Thus, a fifth insulation layer 440 enclosing a lower portion of the preliminary lower electrode structure 430 is provided on the fourth insulation layer 424. The fifth insulation layer 440 may be formed by, for example, a CMP process and/or an etch-back process.

In example embodiments, the lower portion of the preliminary lower electrode structure 430 may be buried in the fifth insulation layer 440. For example, the fifth insulation layer 440 may enclose the first lower electrode layer pattern 432 and a lower portion of the second lower electrode layer pattern 434. Accordingly, the structural stability of a lower electrode structure 442 (see FIG. 13) may be considerably improved. Further, etching damage to the first and the second lower electrode layer patterns 432 and 434 may be prevented because the fifth insulation layer 440 protects the first lower electrode layer pattern 432 in successive etching processes. Therefore, the lower electrode structure 442 may have enhanced electrical characteristics.

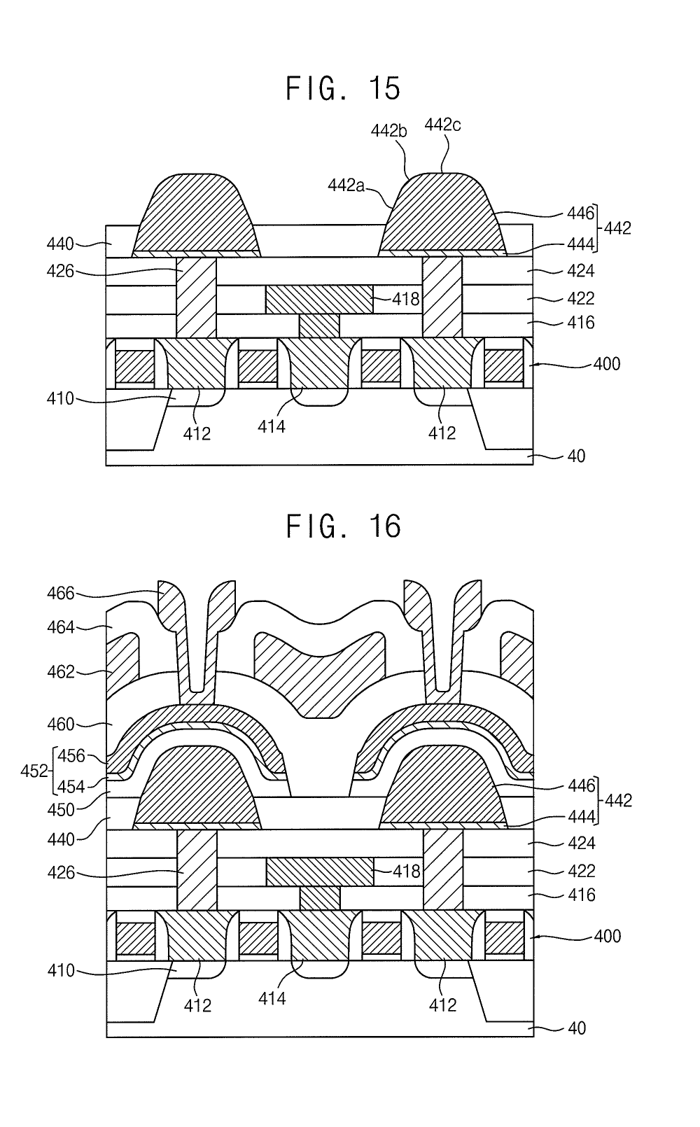

Referring to FIG. 15, the preliminary lower electrode structure 430 is partially etched to form the lower electrode structure 442 over the substrate 40. The lower electrode structure 442 may be formed by, for example, an etch-back process. In example embodiments, the upper portion of the second lower electrode layer pattern 434 is partially removed to provide a second lower electrode 446 on a first lower electrode 444.

The lower electrode structure 442 has an inclined sidewall 442a, an upper surface 442b and a rounded surface 442c between the sidewall 442a and the upper face 442b in accordance with the shape of the second lower electrode 446. The second lower electrode 446 has an upper portion and a lower portion enclosed by the fifth insulation layer 440. The upper portion of the second lower electrode 446 is protruded from the fifth insulation layer 440.

Referring to FIG. 16, a ferroelectric layer, a first upper electrode layer and a second upper electrode layer are sequentially formed on the fifth insulation layer 440. The ferroelectric layer covers the lower electrode structure 442, and the first and the second upper electrode layers are located on the ferroelectric layer.

A second hard mask is formed on the second upper electrode layer, and then the second upper electrode layer, the first upper electrode layer and the ferroelectric layer are patterned to thereby form a ferroelectric layer pattern 450 and an upper electrode structure 452. The upper electrode structure 452 includes a first upper electrode 454 and a second upper electrode 456. The ferroelectric layer pattern 450 covers the lower electrode structure 442 and extends on the fifth insulation layer 440. Therefore, a ferroelectric capacitor having the lower electrode structure 442, the ferroelectric layer pattern 450 and the upper electrode structure 452 is provided over the substrate 40. A lower portion of the ferroelectric capacitor may be buried in the fifth insulation layer 440.

In example embodiments, a third lower electrode may be formed on the second lower electrode 446 and the fifth insulation layer 440. Here, the lower electrode structure may additionally include the third lower electrode.

A sixth insulation layer 460 is formed on the fifth insulation layer 440 to cover the ferroelectric capacitor, and then a first wiring 462 is provided on the sixth insulation layer 460.

After a seventh insulation layer 464 covering the first wiring 462 is formed on the sixth insulation layer 460, a second wiring 466 is formed on the seventh insulation layer 464. The second wiring 466 extends to the second upper electrode 456. Thus, the second wiring 466 may electrically contact with the upper electrode structure 452 of the ferroelectric capacitor. The first and the second wirings 462 and 466 may be formed using, for example, a metal and/or a metal compound.

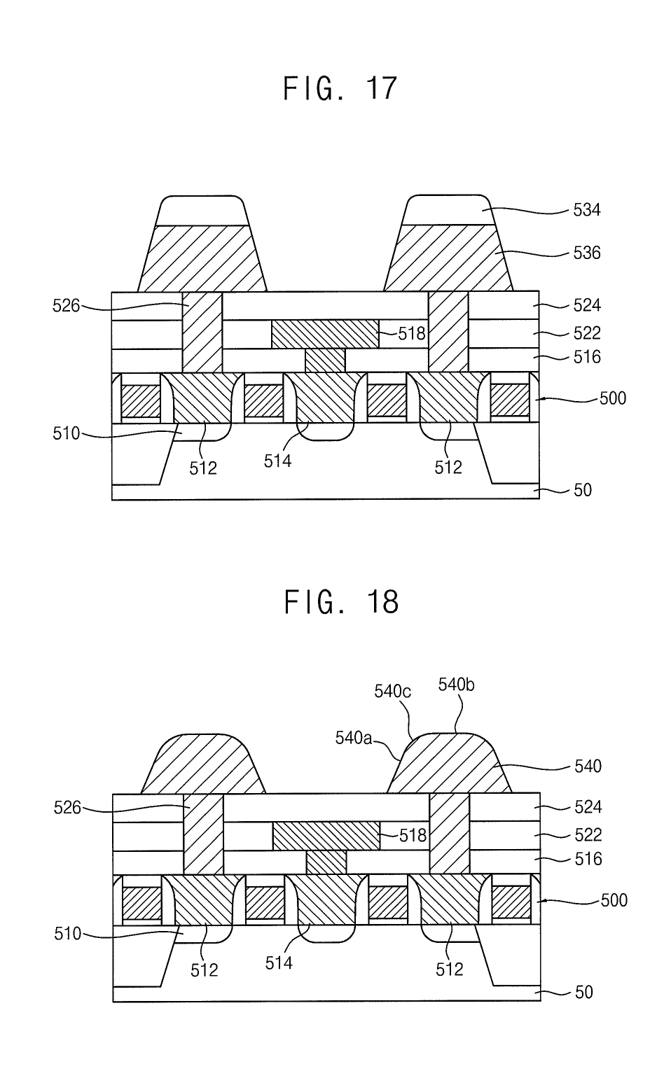

FIGS. 17 to 19 are cross-sectional views illustrating a method of manufacturing a semiconductor device including a capacitor in accordance with example embodiments of the present invention.

Referring to FIG. 17, a conductive structure 500, source/drain regions 510, a first insulation layer, a first pad 512 and a second pad 514 are formed on a substrate 50 by processes substantially the same as those described with reference to FIG. 1. Further, a second insulation layer 516, a bit line 518, a third insulation layer 522 and a fourth insulation layer 534 are provided through processes substantially the same as those described with reference to FIG. 1.

A plug 526 is formed on the first pad 512 through the fourth, the third and the second insulation layers 524, 522 and 516 after partially etching the fourth, the third and the second insulation layers 524, 522 and 516.

A first lower electrode layer is formed on the plug 526 and the fourth insulation layer 524. The first lower electrode layer may have a relatively thick thickness. For example, the first lower electrode layer may have a thickness of about 1,000 Å to about 3,000 Å measured from an upper face of the fourth insulation layer 524. The first lower electrode layer may be formed, for example, using doped polysilicon, a metal and/or a metal compound. For example, the first lower electrode layer may include tungsten, aluminum, copper, titanium, tantalum, titanium nitride, aluminum nitride, tungsten nitride, etc. These may be used alone or in a mixture thereof. The first lower electrode layer may have a single layer structure or a multi layer structure.

In example embodiments, the first lower electrode layer may be formed using a material substantially the same as or substantially similar to that of the plug 526. Alternatively, the plug 526 and the first lower electrode layer may include different materials, respectively.

A first hard mask layer is provided on the first lower electrode layer, and then the first hard mask layer is patterned to form a first hard mask 534 on the first lower electrode layer. The first hard mask 534 may be formed by, for example, a photolithography process.

The first lower electrode layer is etched using the first hard mask 534 as an etching mask to thereby form a preliminary lower electrode structure 536 on the plug 526 and the fourth insulation layer 524. The preliminary lower electrode structure 536 may be formed by, for example, an anisotropic etching process. The preliminary lower electrode structure 536 may have a sidewall inclined by a first angle relative to the substrate 50. For example, the first angle of the sidewall of the preliminary lower electrode structure 536 may be in a range of about 70° to about 80°. However, the first angle of the sidewall of the preliminary lower electrode structure 536 may be adjusted in accordance with the consumption of the first hard mask 534 while forming the preliminary lower electrode structure 536.

As the sidewall of the preliminary lower electrode structure 536 is inclined by the first angle, the preliminary lower electrode structure 536 may have an area gradually reduced along an upward direction with respect to the substrate 50.

Referring to FIG. 18, the preliminary lower electrode structure 536 is partially removed to form a lower electrode structure 540 after removing the first hard mask 534. The lower electrode structure 540 is positioned on the plug 526 and the fourth insulation layer 524.

In example embodiments, an edge portion of the preliminary lower electrode structure 536 is partially removed by an etch-back process, so that the lower electrode structure 540 includes a sidewall 540a, an upper surface 540b and a rounded surface 540c positioned between the sidewall 540a and the upper surface 540b. For example, the lower electrode structure 540 may be formed by partially etching the preliminary lower electrode structure 536 using argon ions.

In example embodiments, the sidewall 540a of the lower electrode structure 540 has a second angle substantially smaller than the first angle of the sidewall of the preliminary lower electrode structure 534. For example, the sidewall 540a of the lower electrode structure 540 may have the second angle of about 60° to about 80° relative to the substrate 50. Accordingly, the lower electrode structure 540 may have an area gradually reduced along an upward direction with respect to the substrate 50.

In example embodiments, the lower electrode structure 540 and the plug 526 may be simultaneously formed. A conductive layer having a sufficient thickness may be formed on the fourth insulation layer 524 to fill a capacitor contact hole formed through the fourth, the third and the second insulation layers 524, 522 and 516. After a hard mask is provided on the conductive layer, the conductive layer may be etched to simultaneously form the preliminary lower electrode structure 536 and the plug 526 as illustrated in FIG. 18. Then, the preliminary lower electrode structure 536 may be partially etched to provide the lower electrode structure 540, thereby simplifying the manufacturing processes for the lower electrode structure 540.

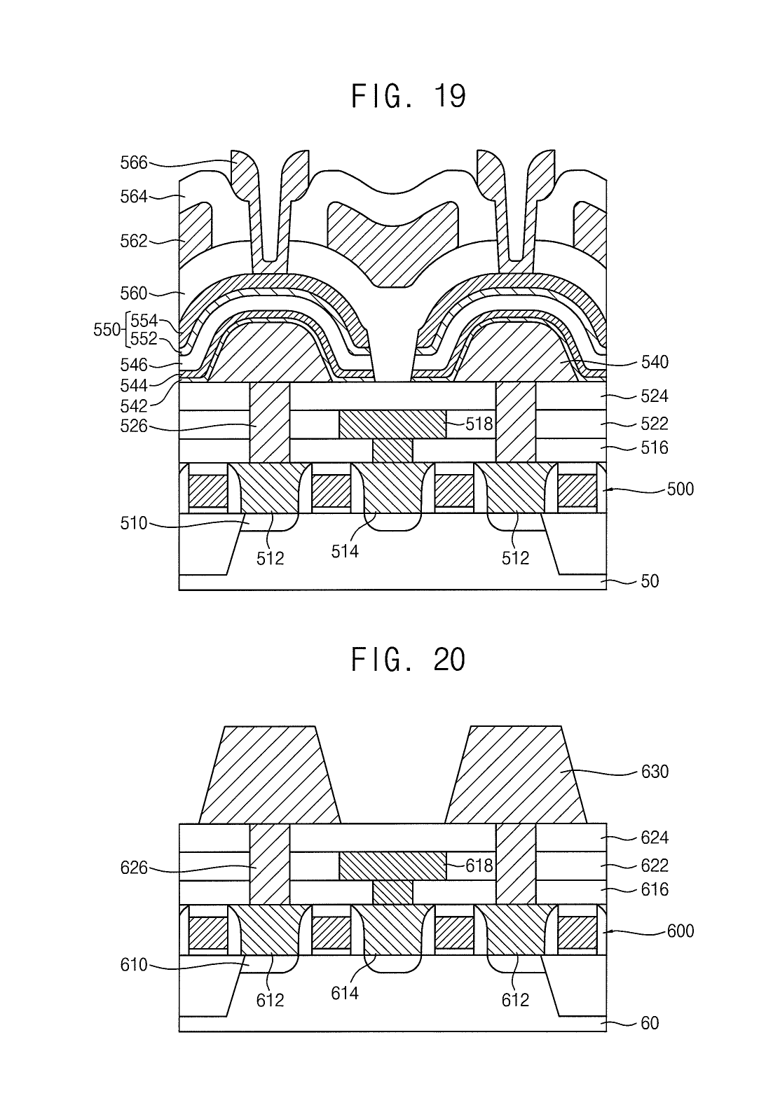

Referring to FIG. 19, a second lower electrode layer and a third lower electrode layer are sequentially formed on the fourth insulation layer 526 to cover the lower electrode structure 540. In this case, the lower electrode structure 540 further include a second lower electrode 542 and a third lower electrode 544, and a lower portion of the lower electrode structure 540 corresponds to a first lower electrode having the sidewall 540a, the upper surface 540b and the rounded surface 540c.

The second lower electrode layer may be formed using, for example, a metal compound. For example, the second lower electrode layer may include titanium nitride, aluminum nitride, titanium aluminum nitride, tungsten nitride, tantalum nitride, titanium silicon nitride, tantalum silicon nitride, etc. These may be used alone or in a mixture thereof. In example embodiments, the second lower electrode layer may have a relatively thin thickness of about 50 Å to about 500 Å based on an upper face of the fourth insulation layer 524.

The third lower electrode layer may be formed using, for example, a metal, a metal compound and/or an alloy. The third lower electrode layer may include, for example, iridium, ruthenium, platinum, palladium, ruthenium oxide, strontium ruthenium oxide (SRO), an alloy of iridium and ruthenium, etc. These may be used alone or in a mixture thereof. The third lower electrode layer may also have a relatively thin thickness of about 50 Å to about 1,000 Å measured form an upper face of the second lower electrode layer.

A ferroelectric layer, a first upper electrode layer and a second upper electrode layer are successively formed on the second lower electrode layer. The ferroelectric layer may include, for example, a ferroelectric material or a ferroelectric material doped with a metal. For example, the ferroelectric layer may be formed using barium titanate, lead zirconate titanate (PZT), strontium bismuth tantalate (SBT), bismuth lanthanum titanate (BLT), lanthanum-doped lead zirconate titanate (PLZT), barium strontium titanate (BST), etc Alternatively, the ferroelectric layer may be formed using, for example, the above-mentioned ferroelectric material doped with calcium, lanthanum, manganese, bismuth, etc.

The first upper electrode layer may be formed using, for example, a metal compound. For example, the first upper electrode layer may include indium tin oxide (ITO), iridium oxide, strontium ruthenium oxide (SRO), strontium titanium oxide (STO), lanthanum nickel oxide (LNO), calcium ruthenium oxide (CRO), etc. The second upper electrode layer may be formed using, for example, a metal, an alloy, a metal compound, etc. For example, the second upper electrode layer may include iridium, ruthenium, platinum, palladium, iridium oxide, ruthenium oxide, strontium ruthenium oxide (SRO), an alloy of iridium-ruthenium, an alloy of iridium-platinum, an alloy of ruthenium-platinum, etc.

Referring now to FIG. 19, a second hard mask is provided on the second upper electrode layer. Next, the second electrode layer, the first upper electrode layer, the ferroelectric layer, the third lower electrode layer and the second lower electrode layer are etched to form the ferroelectric capacitor over the substrate 50.

The ferroelectric capacitor includes the lower electrode structure, a ferroelectric layer pattern 546 and an upper electrode structure 550. As described above, the lower electrode structure includes the first lower electrode 540, the second lower electrode 542 and the third lower electrode 544. The upper electrode structure 550 includes a first upper electrode 552 and a second upper electrode 554.

After removing the second hard mask from the ferroelectric capacitor, a fifth insulation layer 560 covering the ferroelectric capacitor is formed on the fourth insulation layer 524. A first wiring 562 is provided on a portion of the fifth insulation layer 560 between adjacent ferroelectric capacitors.

A sixth insulation layer 564 is formed on the fifth insulation layer 560 to cover the first wiring 562, and then the sixth and the fifth insulation layers 564 and 560 are partially etched to form an opening that exposes the second upper electrode 554.

A second wiring 5666 is formed on the sixth insulation layer 564, the exposed second upper electrode 554 and the inside of the opening.

FIGS. 20 to 22 are cross-sectional views illustrating a method of manufacturing a semiconductor device including a capacitor in accordance with example embodiments of the present invention.

Referring to FIG. 20, a conductive structure 600, source/drain regions 610, a first insulation layer, a first pad 612 and a second pad 614 are formed on a substrate 60 by processes substantially the same as those described with reference to FIG. 1. Additionally, a second insulation layer 616, a bit line 618, a third insulation layer 622, a fourth insulation layer 634 and a plug 626 are formed through processes substantially the same as those described with reference to FIG. 1.

A first lower electrode layer is formed on the plug 626 and the fourth insulation layer 624. The first lower electrode layer is patterned to provide a preliminary lower electrode structure 630 on the plug 626 and the fourth insulation layer 624. The preliminary lower electrode structure 630 may have a sidewall inclined by a first angle with respect to the substrate 60.

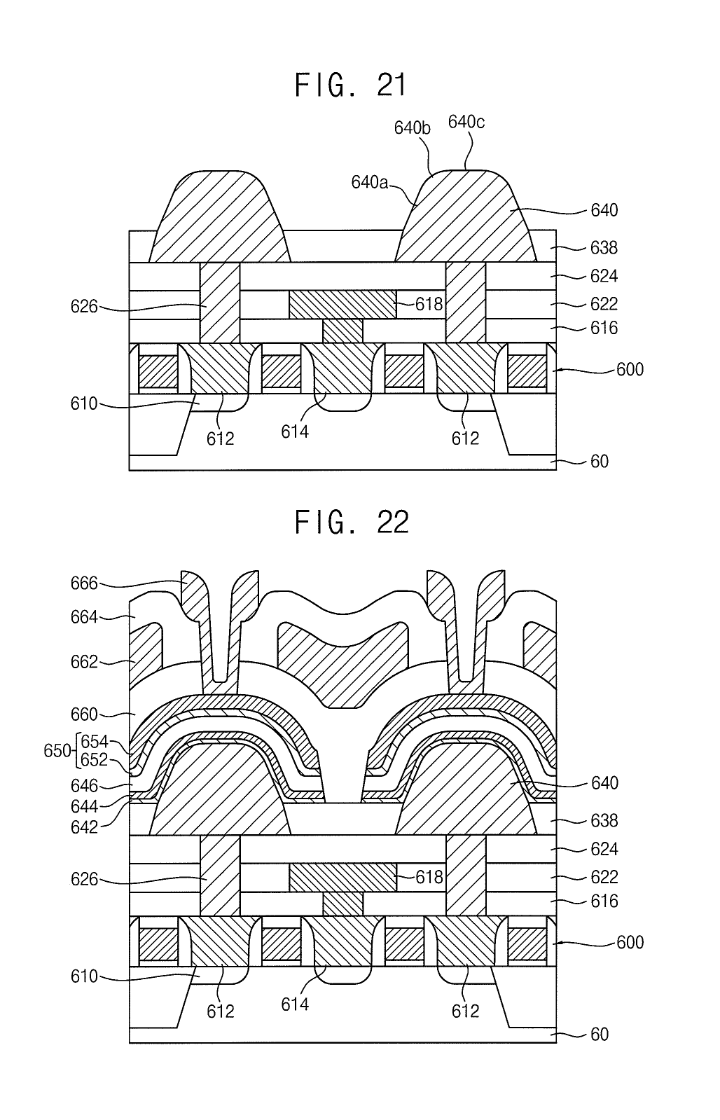

Referring to FIG. 21, a fifth insulation layer 638 is formed on the preliminary lower electrode structure 630 and the fourth insulation layer 624. The fifth insulation layer 638 is partially removed until an upper portion of the preliminary lower electrode structure 630 is exposed. The fifth insulation layer 638 may be partially removed by, for example, a CMP process and/or an etch-back process. When the fifth insulation layer 638 is partially removed, the upper portion of the preliminary lower electrode structure 630 is protruded from the fifth insulation layer 638. Namely, a lower portion of the preliminary lower electrode structure 630 is buried in the fifth insulation layer 638. In other words, the fifth insulation layer 638 may enclose the lower portion of the preliminary lower electrode structure 630.

The preliminary lower electrode structure 630 is partially removed to form a lower electrode structure 640 over the substrate 60. In example embodiments, an edge portion of the preliminary lower electrode structure 630 is removed by an etch-back process, so that the lower electrode structure 640 includes a sidewall 640a, an upper surface 640c and a rounded surface 640b between the sidewall 640a and the upper surface 640c. The sidewall 640a of the lower electrode structure 640 is inclined by a second angle substantially the same as or substantially smaller than the first angle of the sidewall of the preliminary lower electrode structure 630. As a result, an upper portion of the lower electrode structure 640 may be protruded from the fifth insulation layer 638, whereas a lower portion of the lower electrode structure 640 may be buried in the fifth insulation layer 638.

A second lower electrode layer and a third lower electrode layer are formed on the fifth insulation layer 638 to cover the lower electrode structure 640. As described above, the lower electrode structure 640 further includes a second lower electrode 642 (see FIG. 22) and a third lower electrode 644 (see FIG. 22) when the second and the third lower electrode layers are additionally provided on the lower electrode structure 640. Here, the lower electrode structure 640 corresponds to a first lower electrode having the sidewall 640a, the rounded surface 640b and the upper surface 640c.

The second lower electrode layer may be formed using, for example, a metal compound, and the third lower electrode layer may be formed using, for example, a metal, a metal compound and/or an alloy. For example, the second lower electrode layer may include titanium nitride, aluminum nitride, titanium aluminum nitride, tungsten nitride, tantalum nitride, titanium silicon nitride, tantalum silicon nitride, etc. These may be used alone or in a mixture thereof. Further, the third lower electrode layer may include, for example, iridium, ruthenium, platinum, palladium, iridium oxide, ruthenium oxide, strontium ruthenium oxide, iridium-ruthenium alloy, etc. These may be used alone or in a mixture thereof. The second and the third lower electrode layers may be formed by, for example, a CVD process, a sputtering process, an ALD process, an evaporation process, a PLD process, etc.

A ferroelectric layer, a first upper electrode layer and a second upper electrode layer are sequentially formed on the third lower electrode layer. The ferroelectric layer may be formed using, for example, a ferroelectric material or a ferroelectric material doped with metal. The first upper electrode layer may include, for example, a metal compound, and the second upper electrode layer may include, for example, a metal, a metal compound and/or an alloy.

After forming a hard mask on the second upper electrode layer, the second upper electrode layer, the first upper electrode layer, the ferroelectric layer, the third lower electrode layer and the second lower electrode layer are patterned to thereby provide a lower electrode structure, a ferroelectric layer pattern 646 and an upper electrode structure 650. Thus, the ferroelectric capacitor is formed on the plug 626 and the fourth insulation layer 624. Here, a lower portion of the ferroelectric capacitor may be enclosed by the fifth insulation layer 638.

The upper electrode structure 650 includes a first upper electrode 652 formed on the ferroelectric layer pattern 646, and a second upper electrode 654 positioned on the first upper electrode 652. The lower electrode structure includes the first lower electrode 640, the second lower electrode 642 and the third lower electrode 644. Here, the first lower electrode 640 has a lower portion enclosed by the fifth insulation layer 638.

A sixth insulation layer 660 is formed on the fifth insulation layer 638 to cover the ferroelectric capacitor, and then a first wiring 662 is formed on the sixth insulation layer 660. The first wiring 662 may be formed using, for example, a metal and/or a metal compound.

After a seventh insulation layer 664 covering the first wiring 662 is provided on the sixth insulation layer 660, the seventh and the sixth insulation layers 664 and 660 are partially etched to form an opening exposing the second upper electrode 654 of the ferroelectric capacitor.

A conductive layer is formed on the exposed second upper electrode 654, a sidewall of the opening and the seventh insulation layer 664. The conductive layer may be formed, for example, using a metal and/or a metal compound. The conductive layer is partially etched to form a second wiring 666 on the exposed second upper electrode 654, the sidewall of the opening and the seventh insulation layer 664. The second wiring 666 may be formed by, for example, an anisotropic etching process.

According to example embodiments of the present invention, a lower electrode structure of a ferroelectric capacitor may include have a sidewall, a rounded surface and an upper surface. The lower electrode structure may have at least one lower electrode electrically connected to a conductive structure provided on a substrate. The lower electrode structure may have a lower portion buried in an insulation layer formed on the substrate. As the lower electrode structure has the above-described construction, an effective area between the lower electrode structure and a ferroelectric layer pattern may be considerably increased, so that the ferroelectric capacitor including the lower electrode structure may have an improved capacitance. Additionally, the ferroelectric layer pattern may have a uniform crystalline structure because the ferroelectric layer pattern is formed on such as lower electrode structure. Therefore, the ferroelectric capacitor including the lower electrode structure and the ferroelectric layer pattern may have enhanced electrical characteristics. When the ferroelectric capacitor is employed in a semiconductor device such as an FRAM device, the semiconductor device may provide improved electrical characteristics and enhanced storage capacity.

Having described the example embodiments of the present invention, it is further noted that it is readily apparent to those of reasonable skill in the art that various modifications may be made without departing from the spirit and scope of the invention which is defined by the metes and bounds of the appended claims.

What is claimed is:

1. A capacitor comprising:
a lower electrode structure formed on a substrate, the lower electrode structure having an upper surface, a sidewall and a rounded surface between the upper surface and the sidewall;
a ferroelectric layer pattern formed on the upper surface, the sidewall and the rounded surface of the lower electrode structure; and
an upper electrode structure formed on the ferroelectric layer pattern.

2. The capacitor of claim 1, further comprising:
a conductive structure formed on the substrate;
an insulation layer formed on the substrate to cover the conductive structure; and
a plug formed through the insulation layer and electrically connected to the conductive structure,
wherein the lower electrode structure is disposed on the plug and the insulation layer.

3. The capacitor of claim 1, wherein the lower electrode structure comprises:
a first lower electrode formed on the substrate, the first lower electrode including a metal compound; and
a second lower electrode formed on the first lower electrode, the second lower electrode including at least one selected from the group consisting of a metal, a metal compound and an alloy.

4. The capacitor of claim 1, wherein the lower electrode structure comprises:
a first lower electrode formed on the substrate, the first lower electrode including at least one selected from the group consisting of doped polysilicon, a metal and a metal compound;
a second lower electrode formed on the first lower electrode, the second lower electrode including a metal compound; and
a third lower electrode formed on the second lower electrode, the third lower electrode including at least one selected from the group consisting of a metal, a metal compound and an alloy.

5. The capacitor of claim 1, further comprising:
a conductive structure formed on the substrate;
a first insulation layer formed on the substrate to cover the conductive structure;
a plug formed through the first insulation layer and electrically connected to the conductive structure; and
a second insulation layer formed on the plug and the first insulation layer,
wherein a lower portion of the lower electrode structure is buried in the second insulation layer.

6. The capacitor of claim 5, wherein the lower electrode structure comprises:
a first lower electrode formed on the plug and the first insulation layer, the first lower electrode including a metal compound; and
a second lower electrode formed on the first lower electrode, the second lower electrode being partially buried in the second insulation layer and the second lower electrode including at least one selected from the group consisting of a metal, a metal compound and an alloy.

7. The capacitor of claim 5, wherein the lower electrode structure comprises:
a first lower electrode formed on the plug and the first insulation layer, the first lower electrode being partially buried in the second insulation layer, and the first lower electrode including at least one selected from the group consisting of doped polysilicon, a metal and a metal compound; and
a second lower electrode formed on the first lower electrode and the second insulation layer, the second lower electrode including a metal compound.

8. The capacitor of claim 7, wherein the lower electrode structure further comprises a third lower electrode formed on the second lower electrode, the third lower electrode including at least one selected from the group consisting of a metal, a metal compound and an alloy.

9. The capacitor of claim 1, wherein the upper electrode structure comprises:
a first upper electrode formed on the ferroelectric layer pattern, the first upper electrode including a metal compound; and
a second upper electrode formed on the first upper electrode, the second upper electrode including at least one selected from the group consisting of a metal, a metal compound and an alloy.

10. The capacitor of claim 1, wherein the sidewall of the lower electrode structure is inclined by an angle of about 40° to about 80° relative to the substrate.

11. The capacitor of claim 10, wherein the lower electrode structure has an area gradually reduced in an upward direction.

12. A method of manufacturing a capacitor, comprising:
forming a lower electrode structure on a substrate, the lower electrode structure having a sidewall, an upper surface and a rounded surface between the sidewall and the upper surface;
forming a ferroelectric layer pattern on the lower electrode structure; and
forming an upper electrode structure on the ferroelectric layer pattern.

13. The method of manufacturing the capacitor of claim 12, further comprising:
forming a conductive structure on the substrate before forming the lower electrode structure;
forming an insulation layer on the substrate to cover the conductive structure; and
forming a plug on the conductive structure through the insulation layer,
wherein the lower electrode structure is disposed on the plug and the insulation layer.

14. The method of manufacturing the capacitor of claim 12, wherein the forming of the lower electrode structure comprises:
forming a first lower electrode layer on the substrate;
forming a second lower electrode layer on the first lower electrode layer;
forming a preliminary lower electrode structure on the substrate by etching the first lower electrode layer and the second lower electrode layer; and
partially etching the preliminary lower electrode structure to form the lower electrode structure including a first lower electrode and a second lower electrode.

15. The method of manufacturing the capacitor of claim 14, wherein the first lower electrode layer is formed using a metal compound, and the second lower electrode layer is formed using at least one selected from the group consisting of a metal, a metal compound and an alloy.

16. The method of manufacturing the capacitor of claim 15, wherein the first lower electrode layer is formed using at least one selected from the group consisting of titanium nitride, aluminum nitride, titanium aluminum nitride, tantalum nitride, tungsten nitride, titanium silicon nitride and tantalum silicon nitride, and the second lower electrode layer is formed using at least one selected from the group consisting of iridium, platinum, ruthenium, palladium, iridium oxide, ruthenium oxide, strontium ruthenium oxide, and an alloy of iridium and ruthenium.

17. The method of manufacturing the capacitor of claim 14, wherein the preliminary lower electrode structure and the lower electrode structure are formed using an etching gas including a chlorine gas.

18. The method of manufacturing the capacitor of claim 14, wherein the rounded surface of the lower electrode structure is obtained by an etch-back process using argon ions.

19. The method of manufacturing the capacitor of claim 12, wherein the forming of the ferroelectric layer pattern and the upper electrode structure comprise:
forming a ferroelectric layer on the lower electrode structure;
forming at least one upper electrode layer on the ferroelectric layer; and
etching the at least one upper electrode layer and the ferroelectric layer.

20. The method of manufacturing the capacitor of claim 12, wherein the forming of the lower electrode structure comprises:
forming a first lower electrode layer on the substrate;
forming a preliminary lower electrode structure by etching the first lower electrode layer; and
partially etching the preliminary lower electrode structure.

21. The method of manufacturing the capacitor of claim 20, wherein the forming of the lower electrode structure further comprises:
forming a second lower electrode layer on the etched preliminary lower electrode structure;
forming a third lower electrode layer on the second lower electrode layer; and
etching the third lower electrode layer and the second lower electrode layer.

22. The method of manufacturing the capacitor of claim 21, wherein the first lower electrode layer is formed using at least one selected from the group consisting of doped polysilicon, a metal and a metal compound, the second lower electrode layer is formed using a metal compound, and the third lower electrode layer is formed using at least one selected from the group consisting of a metal, a metal compound and an alloy.

23. The method of manufacturing the capacitor of claim 12, wherein the forming of the lower electrode structure comprises:
forming a first insulation layer on the substrate having a conductive structure;
forming a plug through the first insulation layer;
forming a first lower electrode layer on the plug and the first insulation layer;
etching the first lower electrode layer to form a preliminary lower electrode structure;
forming a second insulation layer on the first insulation layer to enclose a lower portion of the preliminary electrode structure; and
partially etching the preliminary lower electrode structure.

24. The method of manufacturing the capacitor of claim 23, wherein the forming of the lower electrode structure further comprises:
forming a second lower electrode layer on the second insulation layer to cover the etched preliminary lower electrode structure;
forming a third lower electrode layer on the second lower electrode layer; and
etching the third lower electrode layer and the second lower electrode layer.

25. A method of manufacturing a semiconductor device, comprising:
providing a conductive structure on a substrate;
forming an insulation layer covering the conductive structure on the substrate;
forming a plug through the insulation layer, the plug being electrically connected to the conductive structure;
forming a lower electrode structure on the plug and the insulation layer, the lower electrode structure including a sidewall, an upper surface and a rounded surface between the sidewall and the upper surface;
forming a ferroelectric layer pattern on the lower electrode structure; and
forming an upper electrode structure on the ferroelectric layer pattern.

26. The method of manufacturing the semiconductor device of claim 25, wherein the conductive structure includes a transistor having source/drain regions formed on the substrate.

27. The method of manufacturing the semiconductor device of claim 25, wherein the forming of the lower electrode structure comprises:
forming a first lower electrode layer on the plug and the insulation layer using a metal compound;
forming a second lower electrode layer on the first lower electrode layer using at least one selected from the group consisting of a metal, a metal compound and an alloy;
etching the second lower electrode layer and the first lower electrode layer to form a preliminary lower electrode structure; and
partially etching the preliminary lower electrode structure to form the lower electrode structure including a first lower electrode and a second lower electrode.

28. The method of manufacturing the semiconductor device of claim 25, wherein the forming of the lower electrode structure comprises:
forming a first lower electrode layer on the plug and the insulation layer using a metal compound;
forming a second lower electrode layer on the first lower electrode layer using at least one selected from the group consisting of a metal, a metal compound and an alloy;
etching the second lower electrode layer and the first lower electrode layer to form a preliminary lower electrode structure;
forming a second insulation layer on the first insulation layer to enclose a lower portion of the preliminary lower electrode structure; and
partially etching the preliminary lower electrode structure.

29. The method of manufacturing the semiconductor device of claim 25, wherein the forming of the lower electrode structure comprises:
forming a first lower electrode layer on the plug and the insulation layer using at least one selected from the group consisting of doped polysilicon, a metal and a metal compound;
etching the first lower electrode layer to form a preliminary lower electrode structure;
forming a second insulation layer on the first insulation layer to enclose a lower portion of the preliminary lower electrode structure;
forming a second lower electrode layer on the second insulation layer to cover the preliminary lower electrode structure using a metal compound;
forming a third lower electrode layer on the second lower electrode layer using at least one selected from the group consisting of a metal, a metal compound and an alloy; and
etching the third lower electrode layer and the second lower electrode layer.
